(19) United States
(12) Patent Application Publication
(10) Pub. No.: US 2023/0402380 A1
(43) Pub. Date: Dec. 14, 2023

(54) PACKAGE COMPRISING A SUBSTRATE WITH A BRIDGE CONFIGURED FOR A BACK SIDE POWER DISTRIBUTION NETWORK

(71) Applicant: QUALCOMM Incorporated, San Diego, CA (US)

(72) Inventors: Biancun XIE, San Diego, CA (US); Shree Krishna PANDEY, San Diego, CA (US)

(21) Appl. No.: 17/835,861

(22) Filed: Jun. 8, 2022

(51) Int. Cl. H01L 23/528; H01L 23/48; H01L 23/28; H01L 21/56; H01L 21/768; H01L 25/065

(52) U.S. Cl. CPC H01L 23/5286; H01L 23/481; H01L 23/28; H01L 21/563; H01L 21/76895; H01L 25/0657; H01L 2225/06513; H01L 2225/06541

(57) ABSTRACT

A package comprising a substrate, a bridge located in the substrate, a first integrated device coupled to the substrate and a second integrated device coupled to the substrate. The bridge includes a bridge substrate; at least one first bridge dielectric layer coupled to a first surface of the bridge substrate; at least one first bridge interconnect located in the at least one first bridge dielectric layer; at least one second bridge dielectric layer coupled to a second surface of the bridge substrate; at least one second bridge interconnect located in the at least one second bridge dielectric layer; and at least one bridge interconnect that extends through the at least one first bridge dielectric layer and the bridge substrate.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages and reduce the overall size of the packages.

### SUMMARY

Various features relate to packages with substrates and integrated devices.

One example provides a package comprising a substrate, a bridge located in the substrate, a first integrated device coupled to the substrate and a second integrated device coupled to the substrate. The bridge includes a bridge substrate; at least one first bridge dielectric layer coupled to a first surface of the bridge substrate; at least one first bridge interconnect located in the at least one first bridge dielectric layer; at least one second bridge dielectric layer coupled to a second surface of the bridge substrate; at least one second bridge interconnect located in the at least one second bridge dielectric layer; and at least one bridge interconnect that extends through the at least one first bridge dielectric layer and the bridge substrate.

Another example provides a device that includes a package. The package comprises a substrate, a bridge located in the substrate, a first integrated device coupled to the substrate, and a second integrated device coupled to the substrate. The bridge comprises a bridge substrate, at least one first bridge dielectric layer coupled to a first surface of the bridge substrate, at least one first bridge interconnect located in the at least one first bridge dielectric layer, at least one second bridge dielectric layer coupled to a second surface of the bridge substrate, at least one second bridge interconnect located in the at least one second bridge dielectric layer, and at least one bridge interconnect that extends through the at least one first bridge dielectric layer and the bridge substrate.

Another example provides a method for fabricating a package. The method provides a substrate. The method places a bridge in the substrate. The bridge comprises a bridge substrate, at least one first bridge dielectric layer coupled to a first surface of the bridge substrate, at least one first bridge interconnect located in the at least one first bridge dielectric layer, at least one second bridge dielectric layer coupled to a second surface of the bridge substrate, at least one second bridge interconnect located in the at least one second bridge dielectric layer, and at least one bridge interconnect that extends through the at least one first bridge dielectric layer and the bridge substrate. The method couples a first integrated device to the substrate. The method couples a second integrated device to the substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate comprising a bridge.

FIG. 2 illustrates an exemplary cross sectional profile view of a package that includes a substrate comprising a bridge.

FIG. 3 illustrates an exemplary cross sectional profile view of a package that includes a substrate comprising a bridge.

FIG. 4 illustrates an exemplary cross sectional profile view of a package that includes a substrate comprising a bridge.

FIG. 5 illustrates an exemplary cross sectional profile view of a bridge.

FIG. 6 illustrates an exemplary cross sectional profile view of a bridge.

FIG. 7 illustrates an exemplary cross sectional profile view of a bridge.

FIGS. 8A-8F illustrate an exemplary sequence for fabricating a bridge.

FIGS. 9A-9D illustrate another exemplary sequence for fabricating a bridge.

FIG. 10 illustrates an exemplary flow chart of a method for fabricating a bridge.

FIGS. 11A-11D illustrate an exemplary sequence for fabricating a package that includes a substrate comprising a bridge.

FIG. 12 illustrates an exemplary flow chart of a method for fabricating a package that includes a substrate comprising a bridge.

FIGS. 13A-13B illustrate an exemplary sequence for fabricating a substrate that includes interconnects.

FIG. 14 illustrates an exemplary flow chart of a method for fabricating a substrate that includes interconnects.

FIG. 15 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate, a bridge located in the substrate, a first integrated device coupled to the substrate and a second integrated device coupled to the substrate. The bridge includes a bridge substrate; at least one first bridge dielectric layer coupled to a first surface of the bridge substrate; at least one first bridge interconnect located in the at least one first bridge dielectric layer; at least one second bridge dielectric layer coupled to a second surface of the bridge substrate; at least one second bridge interconnect located in the at least one second bridge dielectric layer; and at least one bridge interconnect that extends through the at least one first bridge dielectric layer and the bridge substrate. A passive device may be located in the substrate. The bridge may be configured to provide at least one electrical path between the first integrated device and the second integrated device. The passive device is coupled to the bridge. The passive device may be considered part of the bridge. An encapsulation layer may be coupled to the bridge. The encapsulation layer is located in the substrate. The passive device may be coupled to a power distribution network of the bridge. As will be further described below, the package provides a passive device that is located closer to the first integrated device and/or the second integrated device, which helps provide improved package performance, while keeping the package small and thin.

Exemplary Package Comprising a Substrate with a Bridge

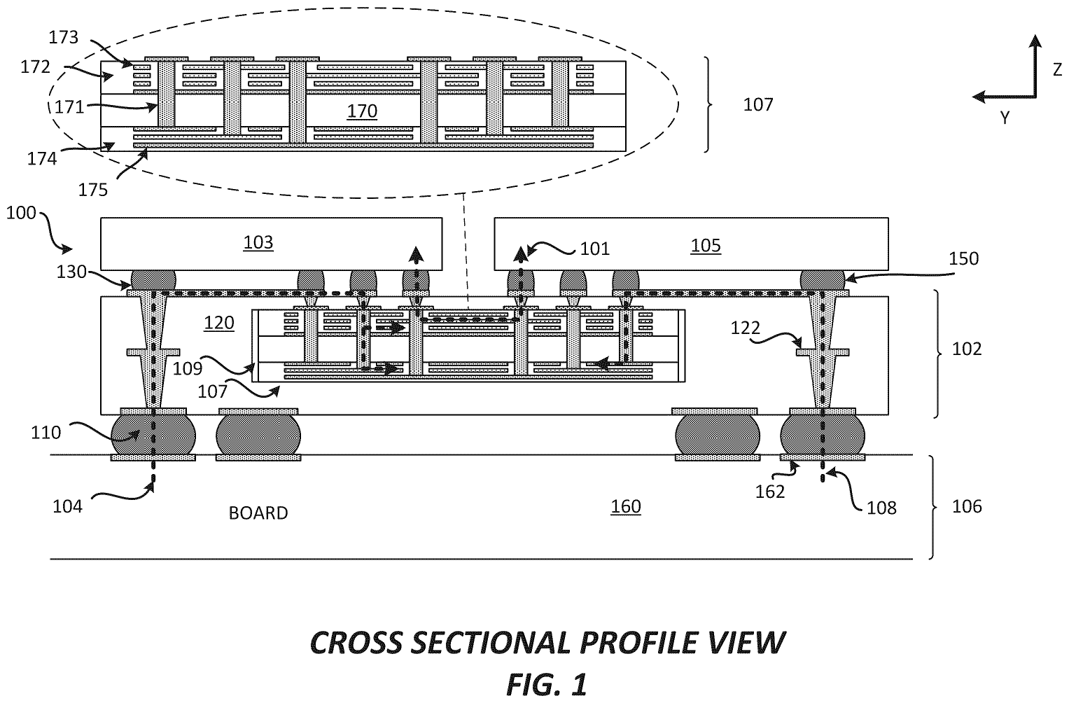

FIG. 1 illustrates a cross sectional profile view of a package 100 that includes a substrate with a bridge. The bridge is configured to provide electrical paths for signals between integrated devices. The bridge is configured to provide an electrical path for a power distribution network (PDN). The package 100 is coupled to a board 106 through a plurality of solder interconnects 110. The board 106 includes at least one board dielectric layer 160 and a plurality of board interconnects 162. The board 106 may include a printed circuit board (PCB).

The package 100 includes a substrate 102, an integrated device 103, an integrated device 105 and a bridge 107. The integrated device 103 may be a first integrated device. The integrated device 105 may be a second integrated device. The substrate 102 includes at least one dielectric layer 120 and a plurality of interconnects 122. The substrate 102 is coupled to the board 106 through the plurality of solder interconnects 110. The plurality of solder interconnects 110 is coupled to the plurality of interconnects 122 and the plurality of board interconnects 162.

The integrated device 103 is coupled to a first surface (e.g., top surface) of the substrate 102 through a plurality of solder interconnects 130. The plurality of solder interconnects 130 is coupled to the integrated device 103 and the plurality of interconnects 122 of the substrate 102. The integrated device 105 is coupled to the first surface (e.g., top surface) of the substrate 102 through a plurality of solder interconnects 150. The plurality of solder interconnects 150 is coupled to the integrated device 105 and the plurality of interconnects 122 of the substrate 102.

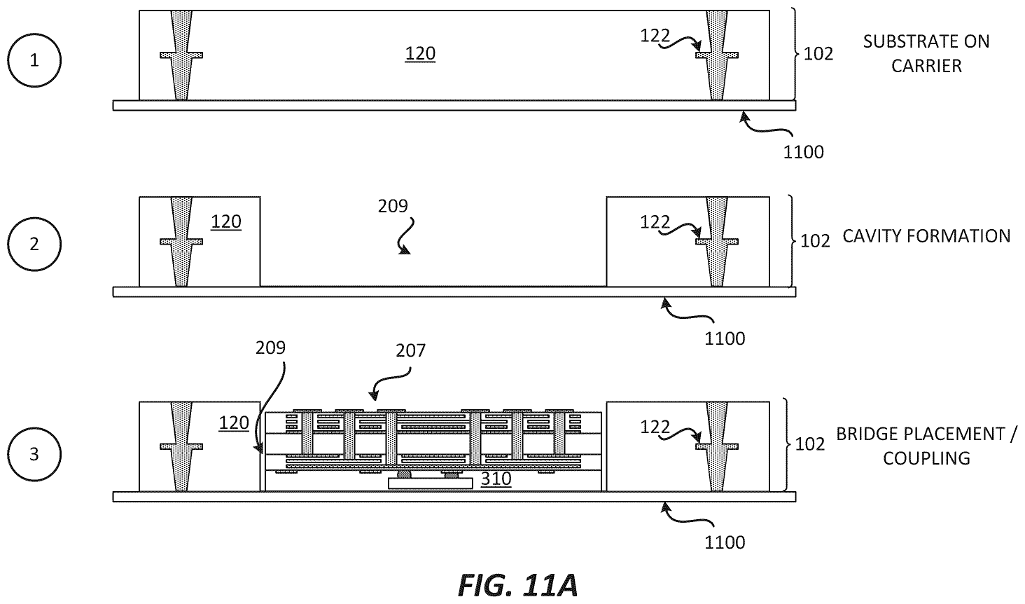

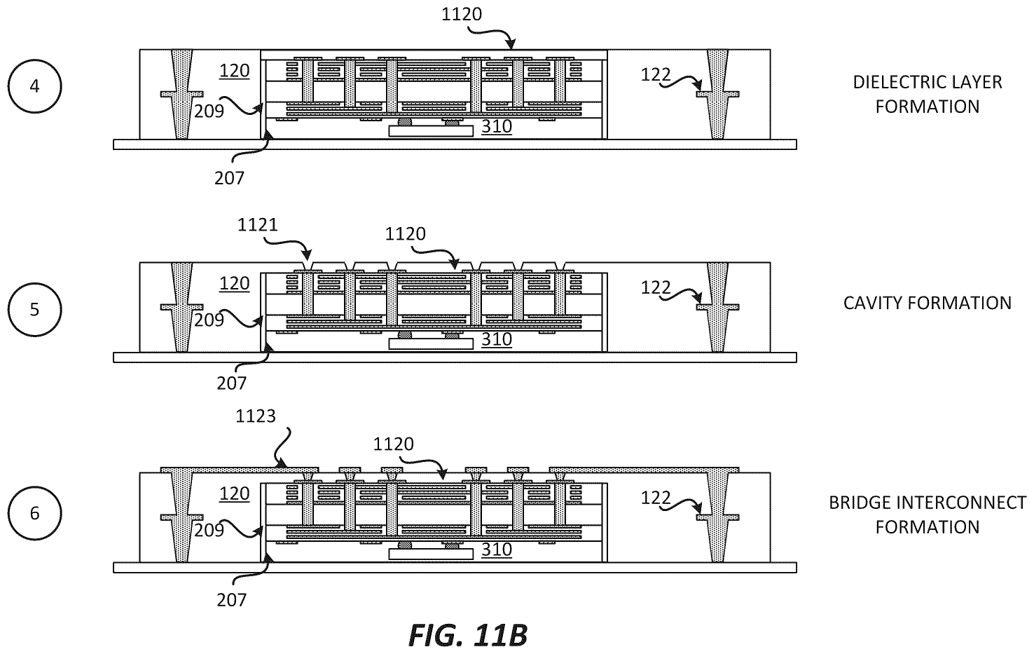

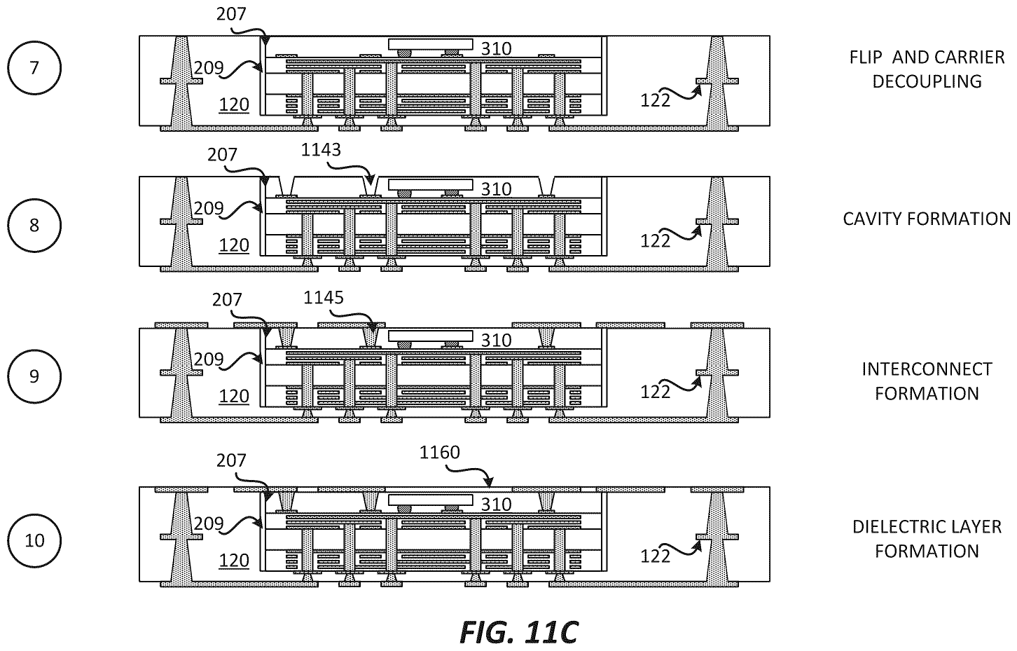

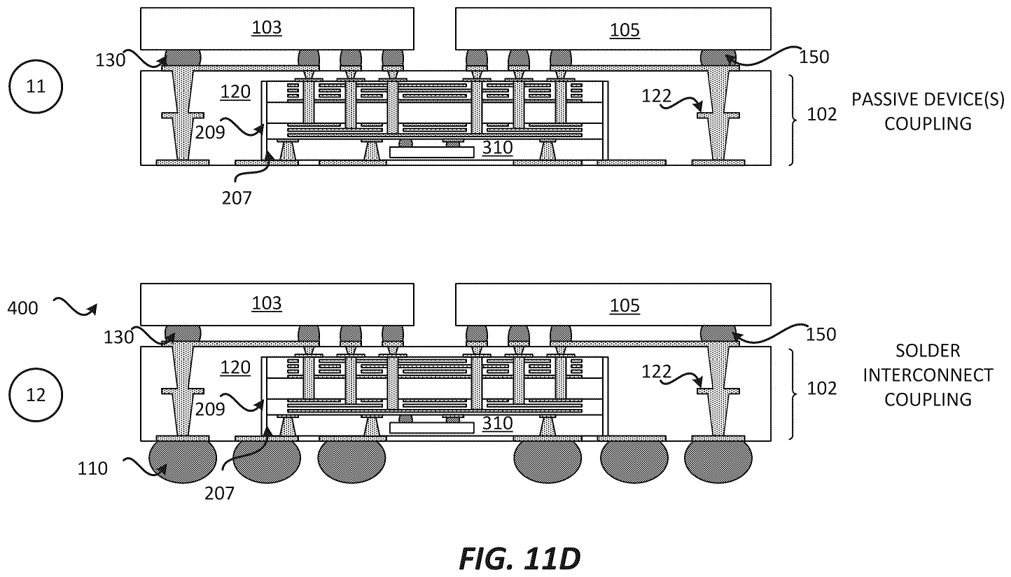

The bridge 107 is located in the substrate 102. The substrate 102 may include a cavity 109. An example of a cavity in a substrate is shown and described below in at least FIG. 11A. The bridge 107 may be located in the cavity 109 of the substrate 102. The bridge 107 is configured to provide a plurality of electrical paths for signals between the integrated device 103 and the integrated device 105. The bridge 107 is configured to provide at least one electrical path for a power distribution network (PDN). The bridge 107 is configured to provide at least one electrical path for power. The bridge 107 is configured to provide at least one electrical path for ground. The bridge 107 may include a front side and a back side. As will be further described below, the bridge 107 is configured to provide at least one electrical path for power and/or ground through a back side of the bridge 107.

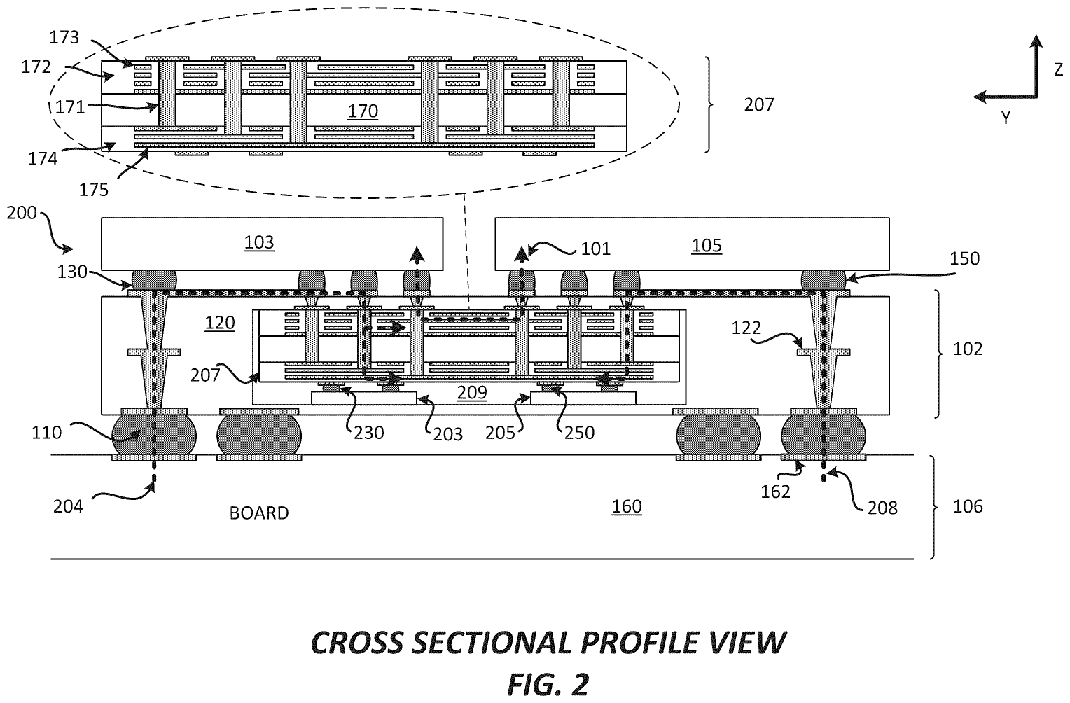

As will be further described below in at least FIG. 2, at least one passive device may be coupled to the bridge 107. For example, at least one passive device may be coupled to the back side of the bridge 107. The passive device coupled to the bridge 107 may be configured to be coupled to power and/or ground. The passive device that is coupled to the bridge 107 may be considered part of the bridge 107.

The bridge 107 includes a bridge substrate 170, at least one bridge dielectric layer 172 (e.g., at least one first bridge dielectric layer), at least one bridge dielectric layer 174 (e.g., at least one second bridge dielectric layer), a plurality of bridge interconnects 171, a plurality of bridge interconnects 173 (e.g., at least one first bridge interconnect) and a plurality of bridge interconnects 175 (e.g., at least one second bridge interconnect). The bridge substrate 170 may include a silicon substrate (e.g., silicon bridge substrate). However, the bridge substrate 170 may include different materials. The at least one bridge dielectric layer 172 is coupled to a first side (e.g., front side, top side) of the bridge substrate 170. The plurality of bridge interconnects 173 is located in and over (e.g., in and above) the at least one bridge dielectric layer 172. The plurality of bridge interconnects 173 may be a plurality of front side bridge interconnects. The at least one bridge dielectric layer 172 and the plurality of bridge interconnects 173 may considered part of a front side of the bridge 107. The at least one bridge dielectric layer 174 is coupled to a second side (e.g., back side, bottom side) of the bridge substrate 170. The plurality of bridge interconnects 175 is located in and over (e.g., in and below) the at least one bridge dielectric layer 174. The at least one bridge dielectric layer 174 and the plurality of bridge interconnects 175 may considered part of a back side of the bridge 107. The plurality of bridge interconnects 175 may be a plurality of back side bridge interconnects. The plurality of bridge interconnects 171 may extend through the front side, the bridge substrate 170, and/or the back side of the bridge 107. For example, the plurality of bridge interconnects 171 may extend (e.g., partially or completely) through the at least one bridge dielectric layer 172, the bridge substrate 170 and/or the at least one bridge dielectric layer 174. The plurality of bridge interconnects 171 may be coupled to the plurality of bridge interconnects 173 and the plurality of bridge interconnects 175. The plurality of bridge interconnects 171 may include a plurality of bridge vias (e.g., bridge via interconnects).

The bridge 107 is configured to provide a plurality of electrical paths for input/output signals, power and/or ground. FIG. 1 illustrates three exemplary electrical paths that a bridge 107 may be configured to provide. It is noted the bridge 107 may be configured to provide more than three electrical paths. Thus, the bridge 107 may be configured to provide other electrical paths.

FIG. 1 illustrates an electrical path 101, an electrical path 104 and an electrical path 108. The electrical path 101 is an example of an electrical path between the integrated device 103 and the integrated device 105. The electrical path 101 is configured to provide an electrical path for input/output (I/O) signals between the integrated device 103 and the integrated device 105. The electrical path 101 may include (i) at least one solder interconnect from the plurality of solder interconnects 130. (ii) at least one interconnect from the plurality of interconnects 122, (iii) at least one bridge interconnect (e.g., 171, 173) from the bridge 107, (iv) at least another interconnect from the plurality of interconnects 122, and (v) at least one solder interconnect from the plurality of solder interconnects 150. The electrical path 101 extends through the front side of the bridge 107. It is noted that there may be a plurality of electrical paths between the integrated device 103 and the integrated device 105 that are similar to the electrical path 101. In one example, the electrical paths between the integrated device 103 and the integrated device 105 that extends through the bridge may each be configured as an electrical path for an I/O signal.

The electrical path 104 is an example of an electrical path that extends through at least the board 106, the substrate 102 and the bridge 107. It is noted that the electrical path 104 may also extend to the integrated device 103 and/or the integrated device 105. In one example, the electrical path 104 is configured to provide an electrical path for power (as part of a power distribution network). The power may be provided to the integrated device 103. In another example, the electrical path 104 is configured to provide an electrical path for ground. The electrical path 104 may include (i) at least one board interconnect from the plurality of board interconnects 162, (ii) at least one solder interconnect from the plurality of solder interconnects 110, (iii) at least one interconnect from the plurality of interconnects 122, and (iv) at least one bridge interconnect (e.g., 171, 173, 175) from the bridge 107. The electrical path 104 may also include a solder interconnect from the plurality of solder interconnect 130. The electrical path 104 may also include a solder interconnect from the plurality of solder interconnect 150. The electrical path 104 may extend through the front side and/or the back side of the bridge 107. In some implementations, there may be a plurality of electrical paths that extend through the board 106, the substrate 102 and the bridge 107. The electrical path 104 may travel through the front side of the bridge 107 and/or the back side of the bridge 107. The electrical path 104 may extend in any direction (e.g., left to right, right to left, up and/or down). One or more currents traveling through the electrical path 104 may travel in any direction (e.g., left to right, right to left, up and/or down). One of these electrical paths may be configured to provide an electrical path for ground, and another of these electrical paths may be configured to provide an electrical path for power (as part of power distribution network).

The electrical path 108 is an example of an electrical path that extends through at least the board 106, the substrate 102 and the bridge 107. It is noted that electrical path 108 may also extend to the integrated device 103 and/or the integrated device 105. In one example, the electrical path 108 is configured to provide an electrical path for power (as part of a power distribution network). The power may be provided to the integrated device 103 and/or the integrated device 105. In another example, the electrical path 108 is configured to provide an electrical path for ground. The electrical path 108 may include (i) at least one board interconnect from the plurality of board interconnects 162, (ii) at least one solder interconnect from the plurality of solder interconnects 110, (iii) at least one interconnect from the plurality of interconnects 122, and (iv) at least one bridge interconnect (e.g., 171, 173, 175) from the bridge 107. The electrical path 108 may also include a solder interconnect from the plurality of solder interconnect 130 and/or a solder interconnect from the plurality of solder interconnects 150. The electrical path 108 may extend through the front side and/or the back side of the bridge 107. In some implementations, there may be a plurality of electrical paths that extend through the board 106, the substrate 102 and the bridge 107. The electrical path 108 may travel through the front side of the bridge 107 and/or the back side of the bridge 107. The electrical path 108 may extend in any direction (e.g., left to right, right to left, up and/or down). One or more currents traveling through the electrical path 108 may travel in any direction (e.g., left to right, right to left, up and/or down). One of these electrical paths may be configured to provide an electrical path for ground, and another of these electrical paths may be configured to provide an electrical path for power (as part of power distribution network).

There are several advantages to the above design and/or configuration. One, the interconnects in/on the back side of the bridge 107 help provide more interconnects to improve the power delivery to the integrated device 103 and/or the integrated device 105. Two, providing a bridge that includes interconnects configured as an electrical path for ground helps improve signal integrity of signals that travel through the bridge 107, which helps improve the performance of the integrated device 103 and/or the integrated device 105.

In some implementations, interconnects on the back side of the bridge 107 may have different thicknesses than interconnects on the front side of the bridge 107. For example, the plurality of bridge interconnects 173 (which are located in/on a front side of the bridge 107) may have a thickness (e.g., first thickness) in a first range of about 1-2 micrometers, and the plurality of bridge interconnects 175 (which are located in/on a back side of the bridge 107) may have a thickness (e.g., second thickness) that is greater than 2 micrometers (e.g., in a second range of about 3-6 micrometers). The increase in thickness of the plurality of bridge interconnects 175 (e.g., back side metal layers) helps improve delivery of power and helps reduce the IR drop across the bridge 107. The thickness mentioned above may refer to the thickness of the metal layers (e.g., M1, M2, M3, M4, M5, M6, M7) and/or metal plane of any of the bridge described in the disclosure. As mentioned above, in some implementations, the substrate 102 may include a passive device. FIG. 2 illustrates a package 200 that includes a substrate with a bridge and at least one passive device. The passive device may be coupled to a power distribution network. The passive device may be configured to help provide effective decoupling for circuits in the package, the integrated devices, the substrate and/or the bridge. The package 200 is similar to the package 100, and thus may include similar components as the package 100.

The package 200 includes the substrate 102, the integrated device 103, the integrated device 105 and a bridge 207. The bridge 207 may be similar to the bridge 107. The substrate 102 includes at least one dielectric layer 120 and a plurality of interconnects 122. The substrate 102 is coupled to the board 106 through the plurality of solder interconnects 110. The plurality of solder interconnects 110 is coupled to the plurality of interconnects 122 and the plurality of board interconnects 162.

The integrated device 103 is coupled to a first surface (e.g., top surface) of the substrate 102 through a plurality of solder interconnects 130. The plurality of solder interconnects 130 is coupled to the integrated device 103 and the plurality of interconnects 122 of the substrate 102. The integrated device 105 is coupled to the first surface (e.g., top surface) of the substrate 102 through a plurality of solder interconnects 150. The plurality of solder interconnects 150 is coupled to the integrated device 105 and the plurality of interconnects 122 of the substrate 102.

The bridge 207 is located in the substrate 102. The substrate 102 may include a cavity 209. The bridge 207 may be located in the cavity 209 of the substrate 102. It is noted that part of the cavity 209 may be filled with gas (e.g., air). The bridge 207 is configured to provide a plurality of electrical paths for signals between the integrated device 103 and the integrated device 105. The bridge 207 is configured to provide at least one electrical path for a power distribution network (PDN). The bridge 207 is configured to provide at least one electrical path for power. The bridge 207 is configured to provide at least one electrical path for ground. The bridge 207 may include a front side and a back side. As will be further described below, the bridge 207 is configured to provide at least one electrical path for power and/or ground through a back side of the bridge 207.

The package 200 also includes a passive device 203 and a passive device 205. The passive device 203 may be a first passive device. The passive device 205 may be a second passive device. A passive device may include a capacitor. The passive device 203 and/or the passive device 205 may be a passive die. The passive device 203 may be located in the substrate 102. The passive device 205 may be located in the substrate 102. The passive device 203 is coupled to the back side of the bridge 207 through a plurality of solder interconnects 230. For example, the passive device 203 may be coupled to bridge interconnects (e.g., 175) of the bridge 207 through the plurality of solder interconnects 230. The passive device 205 is coupled to the back side of the bridge 207 through a plurality of solder interconnects 250. For example, the passive device 205 may be coupled to bridge interconnects (e.g., 175) of the bridge 207 through the plurality of solder interconnects 250.

FIG. 2 illustrates the electrical path 101, an electrical path 204 and an electrical path 208. The electrical path 101 of FIG. 2 may be similar to the electrical path 101 of FIG. 1. The electrical path 204 may be similar to the electrical path 104 of FIG. 1. The electrical path 208 may be similar to the electrical path 108 of FIG. 1. However, as will be further described below, the electrical path 204 includes the passive device 203, and the electrical path 208 includes the passive device 205.

The electrical path 204 is an example of an electrical path that extends through at least the board 106, the substrate 102, the bridge 207 and the passive device 203. It is noted that electrical path 204 may also extend to the integrated device 103 and/or the integrated device 105. In one example, the electrical path 204 is configured to provide an electrical path for power (as part of a power distribution network). The power may be provided to the integrated device 103 and/or the integrated device 105. In another example, the electrical path 204 is configured to provide an electrical path for ground. The electrical path 204 may include (i) at least one board interconnect from the plurality of board interconnects 162, (ii) at least one solder interconnect from the plurality of solder interconnects 110. (iii) at least one interconnect from the plurality of interconnects 122, (iv) at least one bridge interconnect (e.g., 171, 173, 175) from the bridge 207, and (v) a terminal (e.g., solder interconnect 230, interconnect) of the passive device 203. The electrical path 204 may also include a solder interconnect from the plurality of solder interconnects 130 and/or a solder interconnect from the plurality of solder interconnects 150. The electrical path 204 may extend through the front side and/or the back side of the bridge 207. In some implementations, there may be a plurality of electrical paths that extend through the board 106, the substrate 102, the bridge 207 and the passive device 203. One of these electrical paths may be configured to provide an electrical path for ground, and another of these electrical paths may be configured to provide an electrical path for power (as part of power distribution network).

The electrical path 208 is an example of an electrical path that extends through at least the board 106, the substrate 102, the bridge 207, and the passive device 205. It is noted that electrical path 208 may also extend to the integrated device 103 and/or the integrated device 105. In one example, the electrical path 208 is configured to provide an electrical path for power (as part of a power distribution network). The power may be provided to the integrated device 103 and/or the integrated device 105. In another example, the electrical path 208 is configured to provide an electrical path for ground. The electrical path 208 may include (i) at least one board interconnect from the plurality of board interconnects 162, (ii) at least one solder interconnect from the plurality of solder interconnects 110, (iii) at least one interconnect from the plurality of interconnects 122, (iv) at least one bridge interconnect (e.g., 171, 173, 175) from the bridge 207, and (v) a terminal (e.g., solder interconnect 250, interconnect) of the passive device 205. The electrical path 208 may also include a solder interconnect from the plurality of solder interconnect 130 and/or a solder interconnect from the plurality of solder interconnect 150. The electrical path 208 may extend through the front side and/or the back side of the bridge 207. In some implementations, there may be a plurality of electrical paths that extend through the board 106, the substrate 102 and the bridge 207. One of these electrical paths may be configured to provide an electrical path for ground, and another of these electrical paths may be configured to provide an electrical path for power (as part of power distribution network).

There are several advantages to the above design and/or configuration. One, the interconnects in/on the back side of the bridge 207 help provide more interconnects to improve the power delivery to the integrated device 103 and/or the integrated device 105. Two, providing a bridge that includes interconnects configured as an electrical path for ground helps improve signal integrity of signals that travel through the bridge 207, which helps improve the performance of the integrated device 103 and/or the integrated device 105. Three, the passive device 203 and/or the passive device 205 provide improved decoupling capabilities compared to capacitors that are coupled to a bottom surface of the substrate 102. Four, the passive device 203 and/or the passive device 205 being closer to the integrated device(s) may help improve voltage droop.

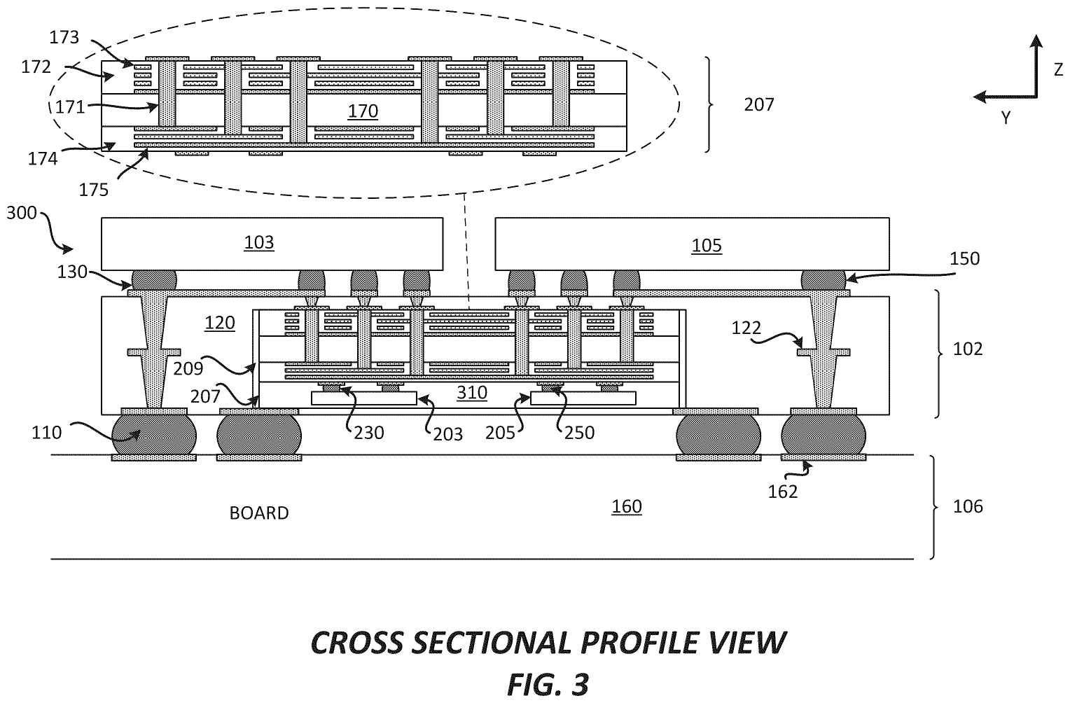

In some implementations, to provide a mechanically robust and stable package, additional materials and/or components may be provided with a package. FIG. 3 illustrates a package 300 that includes an encapsulation layer 310 in a substrate. The package 300 is similar to the package 200, and thus includes similar components as the package 200. The description of the package 200 and its components is also applicable to the package 300. The package 300 includes an encapsulation layer 310 that is located in the substrate 102. The encapsulation layer 310 may be located in the cavity 209 of the substrate 102. The cavity 209 may be filled with gas (e.g., air).

FIG. 3 illustrates an encapsulation layer 310 that encapsulates the passive device 203 and the passive device 205. The encapsulation layer 310 may be coupled to the back side of the bridge 207 and/or is part of the back side of the bridge 207. The encapsulation layer 310 may also encapsulate the bridge 207. The encapsulation layer 310 may include a mold, a resin and/or an epoxy. The encapsulation layer 310 may be a means for encapsulation. The encapsulation layer 310 may be provided by using a compression and transfer molding process, a sheet molding process, or a liquid molding process. It is noted that other materials, such as an underfill, may be used instead of or in combination with the encapsulation layer 310. In some implementations, the passive device 203, the passive device 205 and/or the encapsulation layer 310 may be considered part of the bridge 207. The encapsulation layer 310 helps provide structural stability for the bridge 207, the substrate 102 and/or the package 300.

It is noted that possible electrical paths for the package 300 may be similar to the electrical paths described for the package 100 of FIG. 1, the package 200 of FIG. 2, or any electrical paths described in the disclosure.

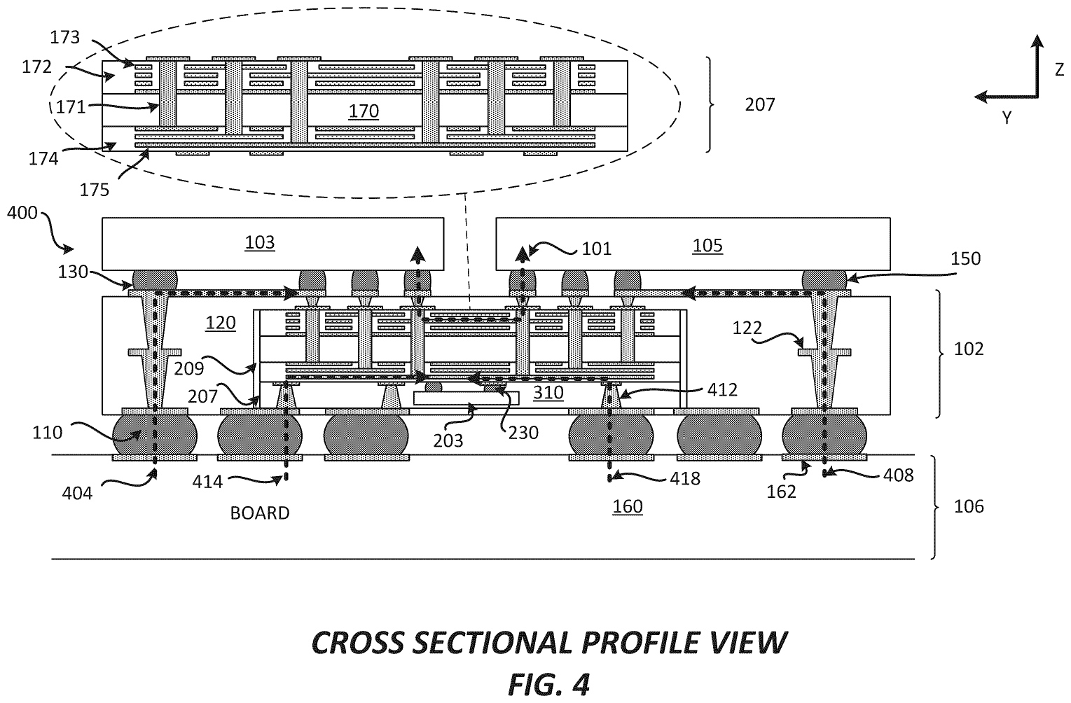

FIG. 4 illustrates a package 400 that includes a bridge with direct back side coupling. The package 400 is similar to the package 300, and thus includes similar components as the package 300. The description of the package 300 and its components is also applicable to the package 400. The package 400 includes a bridge 207 and an encapsulation layer 310 that are located in the substrate 102. The encapsulation layer 310 includes a plurality of interconnects 412 that are configured to allow at least one electrical path through the back side of the bridge 207. The encapsulation layer 310 may be located in the cavity 209 of the substrate 102. The cavity 209 may be filled with gas (e.g., air). In some implementations, the encapsulation layer 310 and/or the plurality of interconnects 412 may be considered part of the bridge 207. In some implementations, the encapsulation layer 310 and/or the plurality of interconnects 412 may be considered part of the substrate 102. The plurality of interconnects 412 may include a plurality of through mold interconnects. The plurality of interconnects 412 may be coupled to the plurality of interconnects 122. The plurality of interconnects 412 may be coupled to the plurality of bridge interconnects 171, the plurality of bridge interconnects 173 and/or the plurality of bridge interconnects 175. The plurality of interconnects 412 may include through mold vias (TMVs). In some implementations, power may travel through an electrical path that includes the plurality of interconnects 412. That is, power may enter through the back side of the bridge 207. The use of the plurality of interconnects 412 as an electrical path for power may help improve voltage droop.

FIG. 4 illustrates the electrical path 101, an electrical path 404, an electrical path 408, and an electrical path 414 and an electrical path 418. The electrical path 101 of FIG. 4 may be similar to the electrical path 101 of FIG. 1.

The electrical path 404 is an example of an electrical path that extends through at least the board 106 and the substrate 102. It is noted that electrical path 404 may also extend to the integrated device 103. In one example, the electrical path 404 is configured to provide an electrical path for power (as part of a power distribution network). The power may be provided to the integrated device 103. In another example, the electrical path 404 is configured to provide an electrical path for ground. The electrical path 404 may include (i) at least one board interconnect from the plurality of board interconnects 162. (ii) at least one solder interconnect from the plurality of solder interconnects 110, and (iii) at least one interconnect from the plurality of interconnects 122. The electrical path 404 may also include a solder interconnect from the plurality of solder interconnect 130. In some implementations, there may be a plurality of electrical paths that extend through the board 106 and the substrate 102. One of these electrical paths may be configured to provide an electrical path for ground, another of these electrical paths may be configured to provide an electrical path for power (as part of power distribution network), and another of these electrical paths may be configured to provide an electrical path for input/output (I/O) signals.

The electrical path 408 is an example of an electrical path that extends through at least the board 106 and the substrate 102. It is noted that the electrical path 408 may also extend to the integrated device 103. In one example, the electrical path 408 is configured to provide an electrical path for power (as part of a power distribution network). The power may be provided to the integrated device 105. In another example, the electrical path 408 is configured to provide an electrical path for ground. The electrical path 408 may include (i) at least one board interconnect from the plurality of board interconnects 162, (ii) at least one solder interconnect from the plurality of solder interconnects 110, and (iii) at least one interconnect from the plurality of interconnects 122. The electrical path 408 may also include a solder interconnect from the plurality of solder interconnect 150. In some implementations, there may be a plurality of electrical paths that extend through the board 106 and the substrate 102. One of these electrical paths may be configured to provide an electrical path for ground, another of these electrical paths may be configured to provide an electrical path for power (as part of power distribution network), and another of these electrical paths may be configured to provide an electrical path for input/output (I/O) signals.

The electrical path 414 is an example of an electrical path that extends through at least the board 106, the substrate 102, the bridge 207 and the passive device 203. It is noted that electrical path 414 may also extend to the integrated device 103. In one example, the electrical path 414 is configured to provide an electrical path for power (as part of a power distribution network). The power may be provided to the integrated device 103. In another example, the electrical path 414 is configured to provide an electrical path for ground. The electrical path 414 may include (i) at least one board interconnect from the plurality of board interconnects 162, (ii) at least one solder interconnect from the plurality of solder interconnects 110, (iii) at least one interconnect from the plurality of interconnects 122, (iv) at least one interconnect from the plurality of interconnects 412, (v) at least one bridge interconnect (e.g., 171, 173, 175) from the bridge 207, and (v) a terminal (e.g., solder interconnect 230, interconnect) of the passive device 203. The electrical path 414 may also include a solder interconnect from the plurality of solder interconnect 130. The electrical path 414 may extend through the encapsulation layer 310 and the back side of the bridge 207. In some implementations, there may be a plurality of electrical paths that extend through the board 106, the substrate 102, the bridge 207 and the passive device 203. One of these electrical paths may be configured to provide an electrical path for ground, and another of these electrical paths may be configured to provide an electrical path for power (as part of power distribution network).

The electrical path 418 is an example of an electrical path that extends through at least the board 106, the substrate 102, the bridge 207 and the passive device 203. It is noted that electrical path 418 may also extend to the integrated device 105. In one example, the electrical path 418 is configured to provide an electrical path for power (as part of a power distribution network). The power may be provided to the integrated device 105. In another example, the electrical path 418 is configured to provide an electrical path for ground. The electrical path 418 may include (i) at least one board interconnect from the plurality of board interconnects 162, (ii) at least one solder interconnect from the plurality of solder interconnects 110, (iii) at least one interconnect from the plurality of interconnects 122, (iv) at least one interconnect from the plurality of interconnects 412, (v) at least one bridge interconnect (e.g., 171, 173, 175) from the bridge 207, and (v) a terminal (e.g., solder interconnect 230, interconnect) of the passive device 203. The electrical path 418 may also include a solder interconnect from the plurality of solder interconnect 150. The electrical path 418 may extend through the encapsulation layer 310 and the back side of the bridge 207. In some implementations, there may be a plurality of electrical paths that extend through the board 106, the substrate 102, the bridge 207 and the passive device 203. One of these electrical paths may be configured to provide an electrical path for ground, and another of these electrical paths may be configured to provide an electrical path for power (as part of power distribution network).

There are several advantages to the above design and/or configuration. One, the interconnects in/on the back side of the bridge 207 help provide more interconnects to improve the power delivery to the integrated device 103 and/or the integrated device 105. Two, providing a bridge that includes interconnects configured as an electrical path for ground helps improve signal integrity of signals that travel through the bridge 207, which helps improve the performance of the integrated device 103 and/or the integrated device 105. Three, the passive device 203 and/or the passive device 205 provide improved decoupling capabilities compared to capacitors that are coupled to a bottom surface of the substrate 102. Four, the passive device 203 and/or the passive device 205 being closer to the integrated device may help improve voltage droop. Five, an electrical path through the encapsulation layer 310 and/or the back side of the bridge 207 may provide a more direct path to the passive device 203 and the integrated device, helping provide improved decoupling of the circuit and/or a shorter path to an integrated device (e.g., 103, 105).

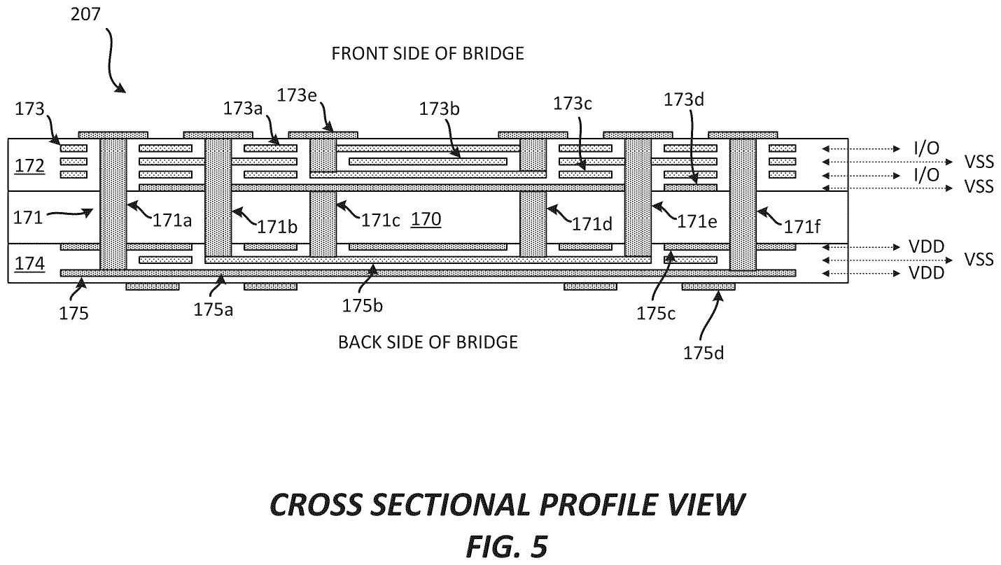

FIG. 5 illustrates an exemplary cross sectional profile view of a bridge 207. As shown in FIG. 5, the bridge 207 includes the bridge substrate 170, at least one bridge dielectric layer 172, at least one bridge dielectric layer 174, a plurality of bridge interconnects 171, a plurality of bridge interconnects 173 and a plurality of bridge interconnects 175. The bridge substrate 170 may include a silicon substrate (e.g., silicon bridge substrate). However, the bridge substrate 170 may include different materials. The at least one bridge dielectric layer 172 is coupled to a first side (e.g., front side, top side) of the bridge substrate 170. The plurality of bridge interconnects 173 is located in and over (e.g., in and above) the at least one bridge dielectric layer 172. The plurality of bridge interconnects 173 may be a plurality of front side bridge interconnects. The at least one bridge dielectric layer 172 and the plurality of bridge interconnects 173 may considered part of a front side of the bridge 207. The at least one bridge dielectric layer 174 is coupled to a second side (e.g., back side, bottom side) of the bridge substrate 170. The plurality of bridge interconnects 175 is located in and over (e.g., in and below) the at least one bridge dielectric layer 174. The at least one bridge dielectric layer 174 and the plurality of bridge interconnects 175 may considered part of a back side of the bridge 207. The plurality of bridge interconnects 175 may be a plurality of back side bridge interconnects. The plurality of bridge interconnects 171 may extend through the front side, the bridge substrate 170, and/or the back side of the bridge 207. For example, the plurality of bridge interconnects 171 may extend (e.g., partially or completely) through the at least one bridge dielectric layer 172, the bridge substrate 170 and/or the at least one bridge dielectric layer 174. The plurality of bridge interconnects 171 may be coupled to the plurality of bridge interconnects 173 and the plurality of bridge interconnects 175. The plurality of bridge interconnects 171 may include a plurality of bridge vias (e.g., bridge via interconnects).

The plurality of bridge interconnects 171 includes at least one bridge interconnect 171a, at least one bridge interconnect 171b, at least one bridge interconnect 171c, at least one bridge interconnect 171d, at least one bridge interconnect 171e and at least one bridge interconnect 171f. The plurality of bridge interconnects 173 includes at least one bridge interconnect 173a, at least one bridge interconnect 173b, at least one bridge interconnect 173c, at least one bridge interconnect 173d and at least one bridge interconnect 173e. The plurality of bridge interconnects 175 includes at least one bridge interconnect 175a, at least one bridge interconnect 175b, at least one bridge interconnect 175c, and at least one bridge interconnect 175d.

In some implementations, the at least one bridge interconnect 173a may be configured to provide at least one electrical path for input/output (I/O) signals. In some implementations, the at least one bridge interconnect 173b may be configured to provide at least one electrical path for ground. In some implementations, the at least one bridge interconnect 173c may be configured to provide at least one electrical path for input/output (I/O) signals. In some implementations, the at least one bridge interconnect 173d may be configured to provide at least one electrical path for ground. In some implementations, the at least one bridge interconnect 173e may be configured to provide at least one electrical path for ground, at least one electrical path for power and/or at least one electrical path for input/output (I/O) signals.

In some implementations, the at least one bridge interconnect 171e may be configured to provide at least one electrical path for ground, at least one electrical path for power and/or at least one electrical path for input/output (I/O) signals.

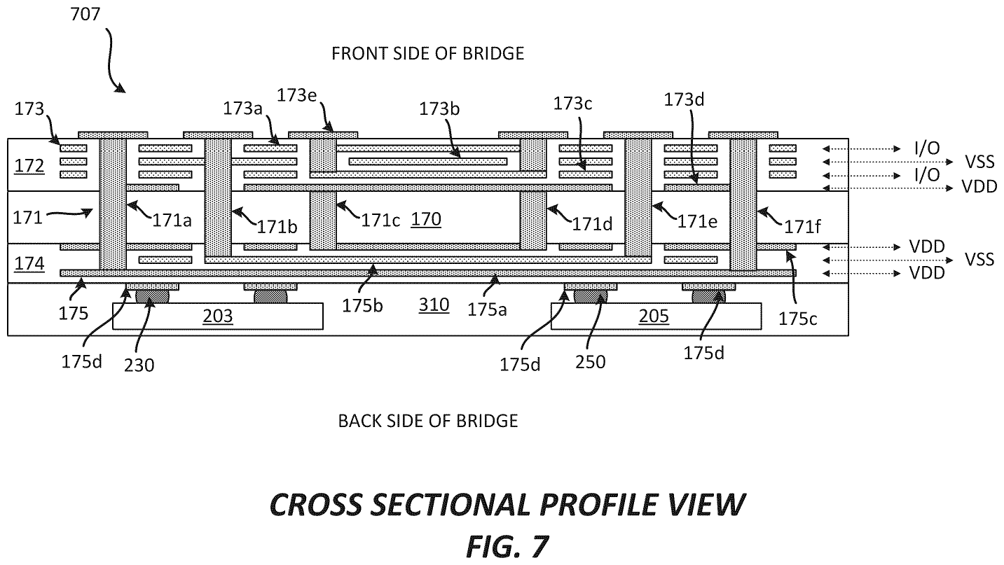

The at least one bridge interconnect 173a may be coupled to the at least one bridge interconnect 173e. The at least one bridge interconnect 173e may include a pad and/or a via. The at least one bridge interconnect 173c may be coupled to the at least one bridge interconnect 173e. The at least one bridge interconnect 173b may be coupled to the at least one bridge interconnect 171b and/or the at least one bridge interconnect 171e. The at least one bridge interconnect 175b may be coupled to the at least one bridge interconnect 171b and/or the at least one bridge interconnect 171e. The at least one bridge interconnect 173d may be coupled to the at least one bridge interconnect 171a and/or the at least one bridge interconnect 171f. The at least one bridge interconnect 175c may be coupled to the at least one bridge interconnect 171a and/or the at least one bridge interconnect 171f. As will be further described in FIG. 7, some implementations may have different paths and/or use different metal planes and/or metal layers for power, ground and/or I/O signals. FIG. 5 illustrates that one metal layer or one metal plane may be configured to provide at least one electrical path for I/O signals, another metal layer or another metal plane may be configured to provide at least one electrical path for other I/O signals, and a metal layer or metal plane located between the metal layers or metal planes, is configured to provide at least one electrical path for ground. This metal layer or metal layer for ground, is configured to help isolate signals on different metal layers or metal planes, as well as different signals on the same metal layer or metal plane.

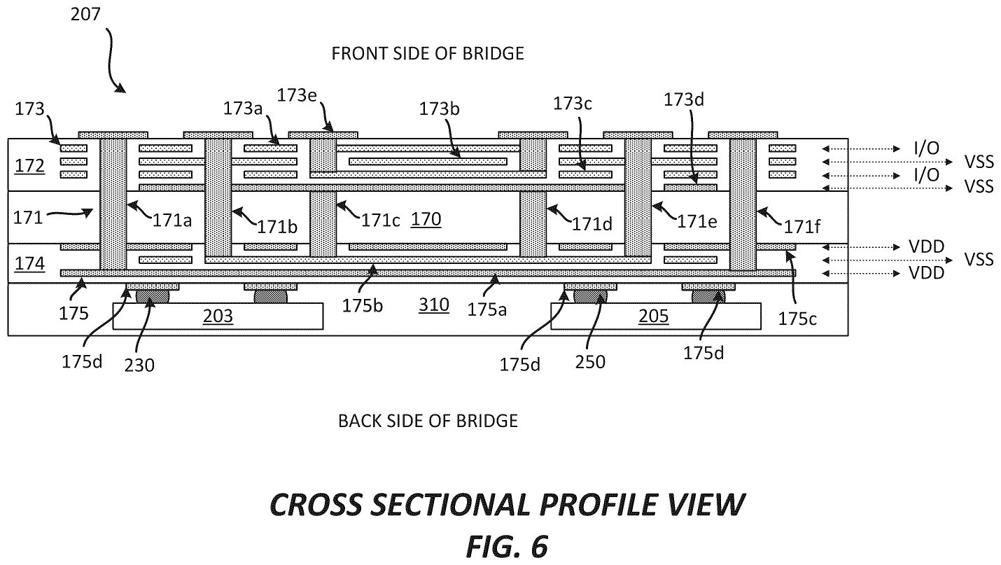

FIG. 6 illustrates an exemplary cross sectional profile view of the bridge 207. The bridge 207 of FIG. 6 is similar to the bridge 207 of FIG. 5. However, the bridge 207 of FIG. 6 also includes a passive device 203, a passive device 205 and an encapsulation layer 310. The passive device 203 is coupled to the back side of the bridge 207 through a plurality of solder interconnects 230. For example, the passive device 203 may be coupled to the at least one bridge interconnect 175d through the plurality of solder interconnects 230. The passive device 205 is coupled to the back side of the bridge 207 through a plurality of solder interconnects 250. For example, the passive device 205 may be coupled to the at least one bridge interconnect 175d through the plurality of solder interconnects 250. The encapsulation layer 310 may encapsulate the passive device 203 and/or the passive device 205. The encapsulation layer 310 may be coupled to a back side of the bridge 207. For example, the encapsulation layer 310 may be coupled to a back side surface of the at least one bridge dielectric layer 174. The passive device 203, the passive device 205 and/or the encapsulation layer 310 may or may not be considered part of the bridge 207.

FIG. 7 illustrates an exemplary cross sectional profile view of a bridge 707. The bridge 707 includes the same or similar components as the bridge 207 of FIG. 6. Thus, the bridge 707 of FIG. 7 may be similar to the bridge 207 of FIG. 5 and/or FIG. 6. However, the bridge 707 of FIG. 7 has different arrangements and/or configurations of electrical paths for power, ground and I/O signals. As shown in FIG. 7, the front side of the bridge 707 includes interconnects that are configured to provide electrical paths for I/O signals, power and ground, and the back side of the bridge 707 is configured to provide electrical paths for power and/or ground. For example, at least a portion of a metal layer (from the plurality of bridge interconnects 173) of the front side of the bridge 707 may be configured to provide an electrical path for I/O signals, at least a portion of another metal layer (from the plurality of bridge interconnects 173) of the front side of the bridge 707 may be configured to provide an electrical path for ground, and at least a portion of yet another metal layer (from the plurality of bridge interconnects 173) of the front side of the bridge 707 may be configured to provide an electrical path for power. Similarly, at least a portion of a metal layer (from the plurality of bridge interconnects 175) of the back side of the bridge 707 may be configured to provide an electrical path for ground, and at least a portion of another metal layer (from the plurality of bridge interconnects 175) of the back side of the bridge 707 may be configured to provide an electrical path for power.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filters, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 103, 105) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to fabrication processes for other types of integrated devices, which can help lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that performs several functions may reduce the overall cost of a package relative to using a single chip to perform all of the functions of a package.

The package (e.g., 100, 200, 300, 400) may be implemented in a radio frequency (RF) package. The RF package may be a radio frequency front end (RFFE) package. A package (e.g., 100, 200, 300, 400) may be configured to provide Wireless Fidelity (WiFi) communication and/or cellular communication (e.g., 2G, 3G, 4G, 5G). The packages (e.g., 100, 300) may be configured to support Global System for Mobile (GSM) Communications, Universal Mobile Telecommunications System (UMTS), and/or Long-Term Evolution (LTE). The packages (e.g., 100, 300) may be configured to transmit and receive signals having different frequencies and/or communication protocols.

Having described various packages with a substrate comprising a bridge, a sequence for fabricating a bridge will now be described below.

### Exemplary Sequence for Fabricating a Bridge

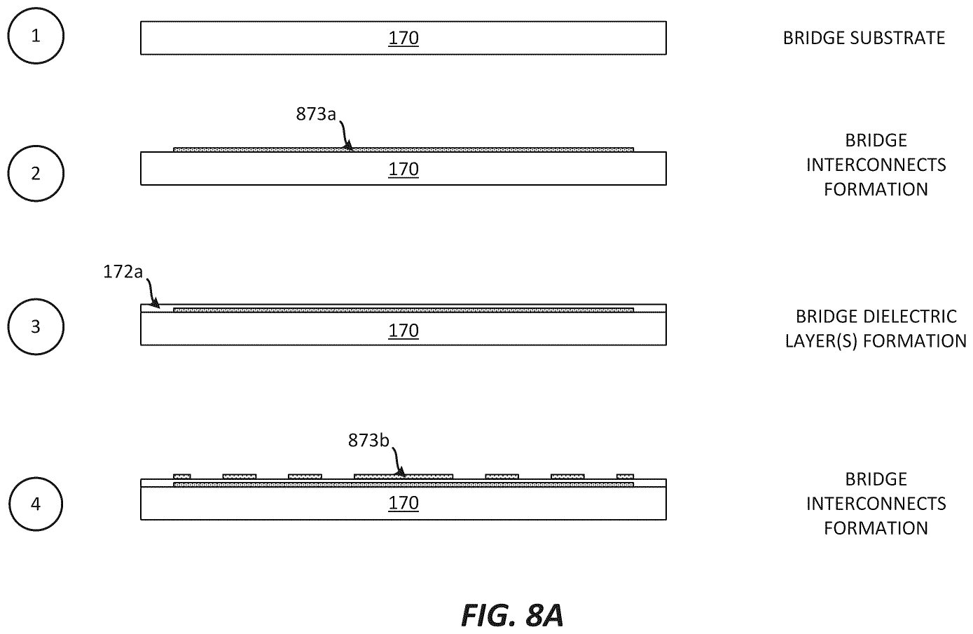

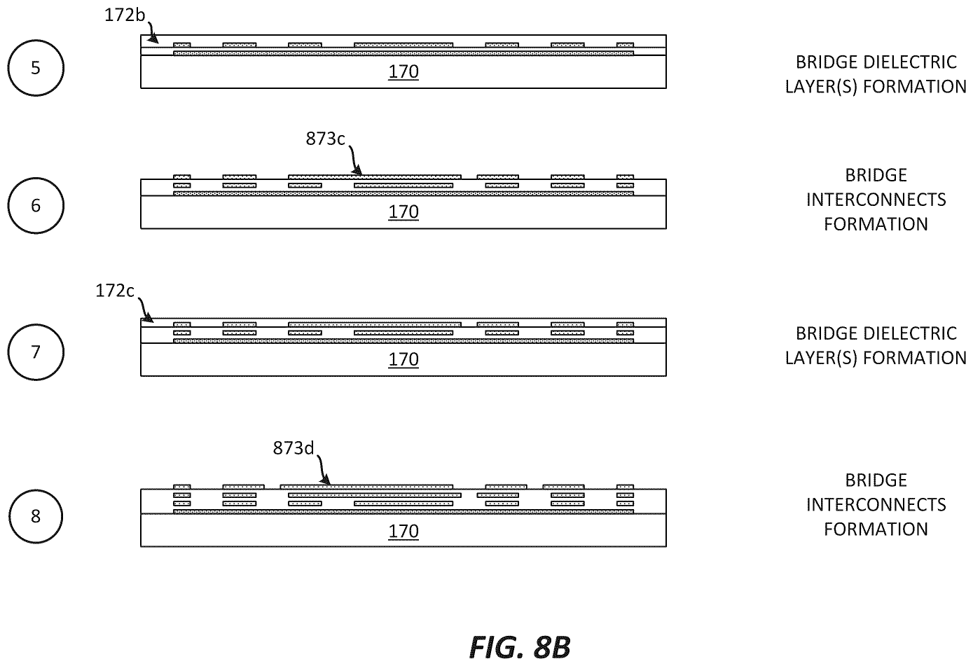

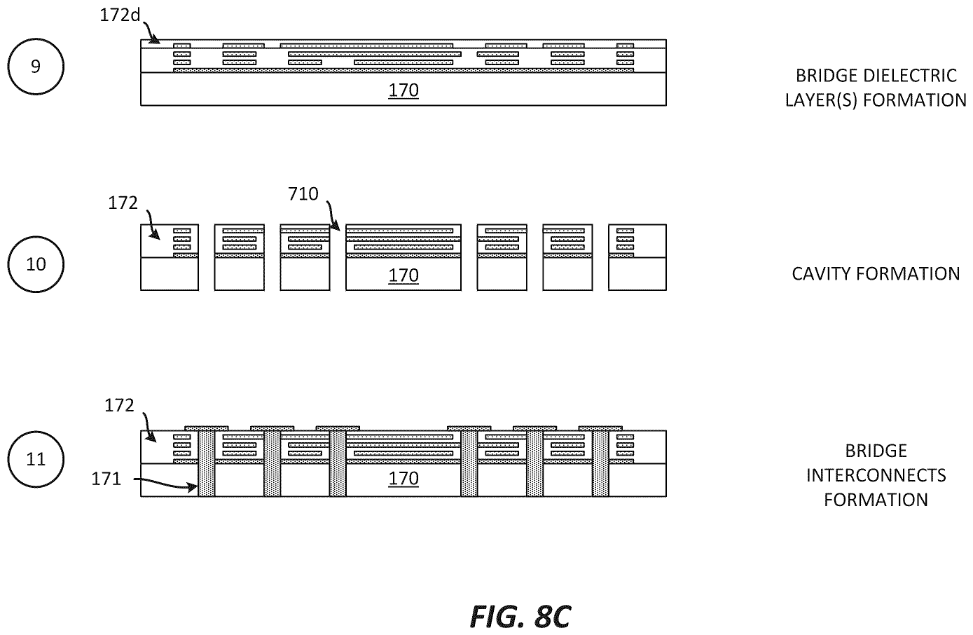

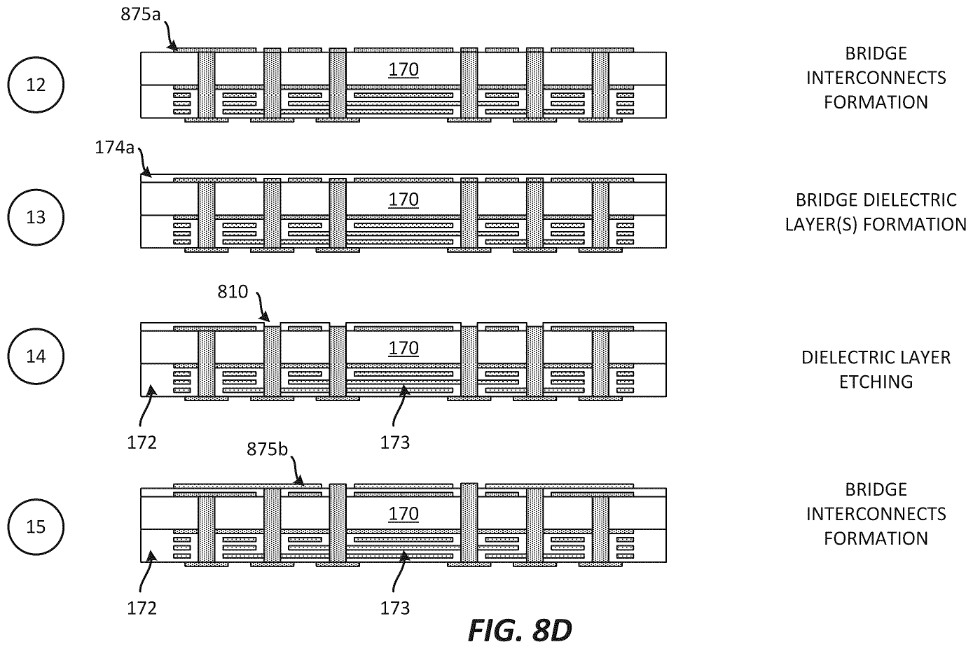

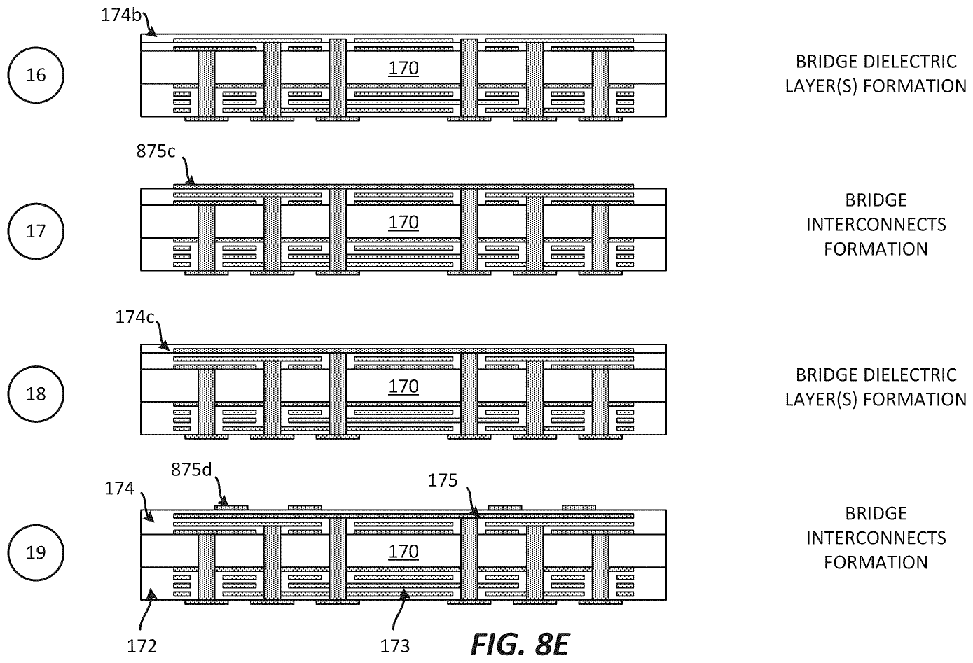

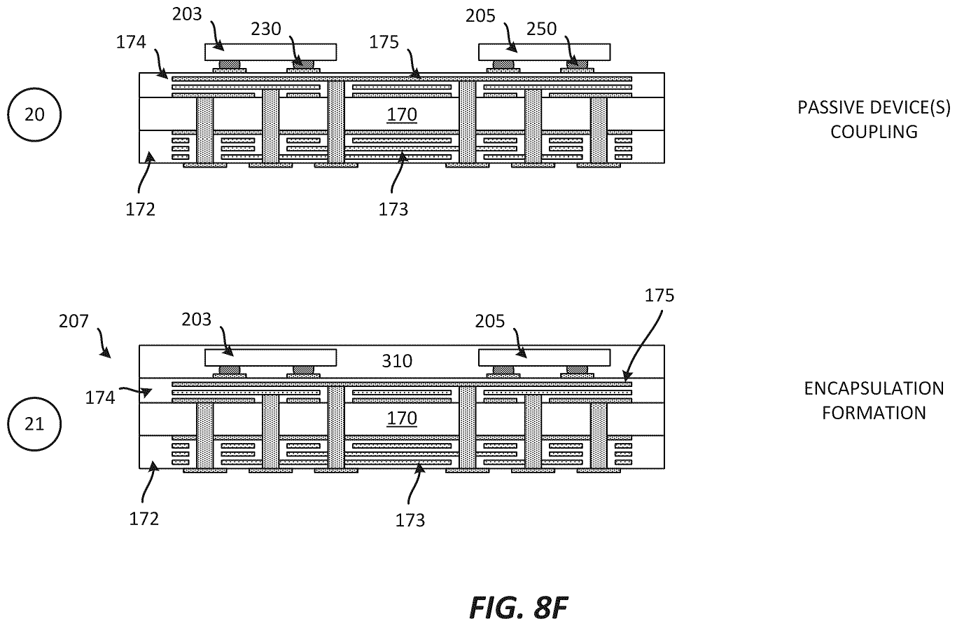

In some implementations, fabricating a bridge includes several processes. FIGS. 8A-8F illustrate an exemplary sequence for providing or fabricating a bridge. In some implementations, the sequence of FIGS. 8A-8F may be used to provide or fabricate the bridge 207. However, the process of FIGS. 8A-8F may be used to fabricate any of the bridges (e.g., 107, 707) described in the disclosure.

It should be noted that the sequence of FIGS. 8A-8F may combine one or more stages in order to simplify and/or clarify the sequence for providing or fabricating a bridge. In some implementations, the order of the processes may be changed or modified. In some implementations, one or more of processes may be replaced or substituted without departing from the scope of the disclosure.

Stage 1, as shown in FIG. 8A, illustrates a state after a bridge substrate 170 is provided. The bridge substrate 170 may include a silicon substrate.

Stage 2 illustrates a state after a plurality of bridge interconnects 873a are formed over a first surface of the bridge substrate 170. The plurality of bridge interconnects 873a may be formed above the bridge substrate 170. A plating process may be used to form the plurality of bridge interconnects 873a.

Stage 3 illustrates a state after a bridge dielectric layer 172a is formed over the first surface of the bridge substrate 170 and the plurality of bridge interconnects 873a. A deposition and/or lamination process may be used to form the bridge dielectric layers 172a.

Stage 4 illustrates a state after a plurality of bridge interconnects 873b are formed over the bridge dielectric layer 172a. The plurality of bridge interconnects 873b may be formed above the bridge dielectric layer 172a. A plating process may be used to form the plurality of bridge interconnects 873b.

Stage 5, as shown in FIG. 8B, illustrates a state after a bridge dielectric layer 172b is formed over the plurality of bridge interconnects 873b and the bridge dielectric layer 172a. A deposition and/or lamination process may be used to form the bridge dielectric layer 172b.

Stage 6 illustrates a state after a plurality of bridge interconnects are formed over the bridge dielectric layer 172b. The plurality of bridge interconnects 873c may be formed above the bridge dielectric layer 172b. A plating process may be used to form the plurality of bridge interconnects 873c.

Stage 7 illustrates a state after a bridge dielectric layer 172c is formed over the plurality of bridge interconnects 873c and the bridge dielectric layer 172b. A deposition and/or lamination process may be used to form the bridge dielectric layer 172c.

Stage 8 illustrates a state after a plurality of bridge interconnects are formed over the bridge dielectric layer 172c. The plurality of bridge interconnects 873d may be formed above the bridge dielectric layer 172c. A plating process may be used to form the plurality of bridge interconnects 873d.

Stage 9, as shown in FIG. 8C, illustrates a state after a bridge dielectric layer 172d is formed over the plurality of bridge interconnects 873d and the bridge dielectric layer 172c. A deposition and/or lamination process may be used to form the bridge dielectric layer 172d.

Stage 10 illustrates a state after a plurality of cavities 710 are formed in the bridge substrate 170 and the at least one bridge dielectric layer 172. The bridge dielectric layer 172 may represent and/or include the bridge dielectric layer 172a, 172b, 172c and/or 172d. The plurality of cavities 710 may be formed using a laser ablation process.

Stage 11 illustrates a state after a plurality of bridge interconnects 171 that extend through the bridge substrate 170 and the at least one bridge dielectric layer 172. A plating process may be used to form the plurality of bridge interconnects 171.

Stage 12, as shown in FIG. 8D illustrates a state after a plurality of bridge interconnects are formed over a second surface of the bridge substrate 170. Stage 12 illustrates a state after the bridge has been flipped, and interconnects are formed on the other surface. The plurality of bridge interconnects 875a may be formed above (or below depending on the orientation of the bridge substrate) the bridge substrate 170. A plating process may be used to form the plurality of bridge interconnects 875a.

Stage 13 illustrates a state after a bridge dielectric layer 174a is formed over the second surface of the bridge substrate 170 and the plurality of bridge interconnects 875a. A deposition and/or lamination process may be used to form the bridge dielectric layers 174a.

Stage 14 illustrates a state after a plurality of cavities 810 are formed in the bridge dielectric layer 174a. An etching process (e.g., photo etching process) may be used to form the cavities.

Stage 15 illustrates a state after a plurality of bridge interconnects 875b are formed over the bridge dielectric layer 174a. The plurality of bridge interconnects 875b may be formed above the bridge dielectric layer 174a and the plurality of bridge interconnects 875a. A plating process may be used to form the plurality of bridge interconnects 875b.

Stage 16, as shown in FIG. 8E, illustrates a state after a bridge dielectric layer 174b is formed over the plurality of bridge interconnects 875b and the bridge dielectric layer 174a. A deposition and/or lamination process may be used to form the bridge dielectric layer 174b.

Stage 17 illustrates a state after a plurality of bridge interconnects 875c are formed over the bridge dielectric layer 174b. The plurality of bridge interconnects 875c may be formed above the bridge dielectric layer 174b. Before the plurality of bridge interconnects 875c are formed, a plurality of cavities may be formed in the bridge dielectric layer 174b in a similar manner as described at Stage 14 above. A plating process may be used to form the plurality of bridge interconnects 875c.

Stage 18 illustrates a state after a bridge dielectric layer 174c is formed over the plurality of bridge interconnects 875c and the bridge dielectric layer 174b. A deposition and/or lamination process may be used to form the bridge dielectric layer 174c.

Stage 19 illustrates a state after a plurality of bridge interconnects 875d are formed over the bridge dielectric layer 174. The bridge dielectric layer 174 may represent and/or include the bridge dielectric layer 174a, 174b, and/or 174c. The plurality of bridge interconnects 875d may be formed above the bridge dielectric layer 174. Before the plurality of bridge interconnects 875d are formed, a plurality of cavities may be formed in the bridge dielectric layer 174c in a similar manner as described at Stage 14 above. A plating process may be used to form the plurality of bridge interconnects 875d.

Stage 20, as shown in FIG. 8F, illustrates a state after a passive device 203 and a passive device 205 are coupled to the plurality of bridge interconnects 175. The passive device 203 may be coupled to the plurality of bridge interconnects 175 through the plurality of solder interconnects 230. The passive device 205 may be coupled to the plurality of bridge interconnects 175 through the plurality of solder interconnects 250. A solder reflow process may be used to couple the passive device 203 and/or the passive device 205.

Stage 21 illustrates a state after an encapsulation layer 310 is formed. The encapsulation layer 310 is coupled to a surface of the bridge 207. For example, the encapsulation layer 310 is coupled to the at least one bridge dielectric layer 174. The encapsulation layer 310 may encapsulate the passive device 203 and/or the passive device 205. The encapsulation layer 310 may include a mold, a resin and/or an epoxy. The encapsulation layer 310 may be a means for encapsulation. The encapsulation layer 310 may be provided by using a compression and transfer molding process, a sheet molding process, or a liquid molding process. Stage 21 illustrates an example of the bridge 207 that includes a bridge substrate 170, a plurality of bridge interconnects 171, at least one bridge dielectric layer 172, a plurality of bridge interconnects 173, at least one bridge dielectric layer 174, a plurality of bridge interconnects 175, a passive device 203, a passive device 205 and an encapsulation layer 310.

FIGS. 8A-8F illustrate a process for fabricating a bridge where the front side of the bridge is fabricated, followed by the bridge interconnects in the bridge substrate, and then the back side of the bridge is fabricated. Some implementations may fabricate the bridge using a different process and/or a different sequence. For example, in some implementations, the front side and the back side of the bridge may be fabricated concurrently and the bridge interconnects (e.g., through substrate vias) extending from the front side of the bridge, the bridge substrate and the back side of the bridge, may be fabricated.

### Exemplary Sequence for Fabricating a Bridge

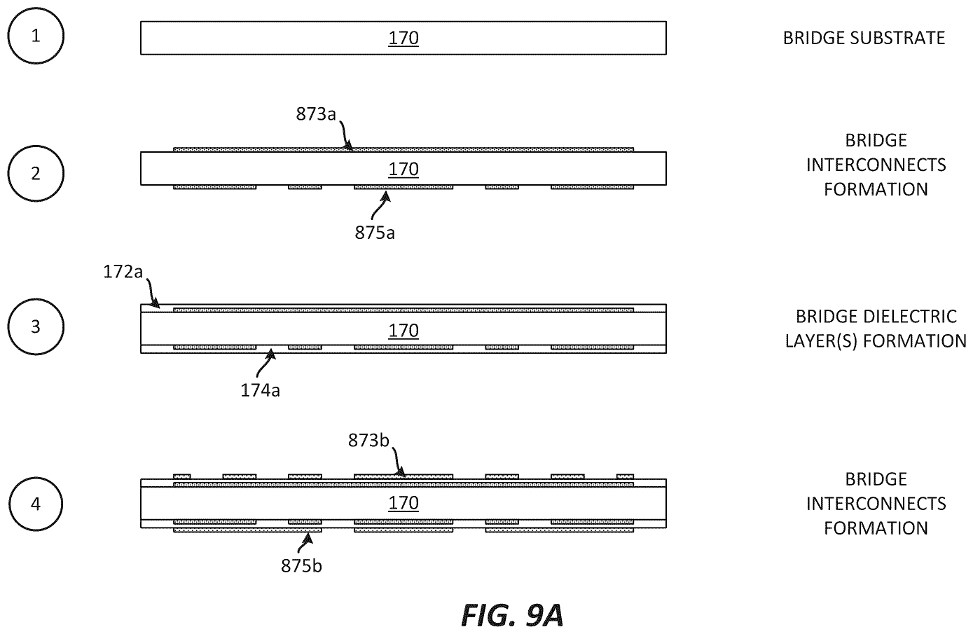

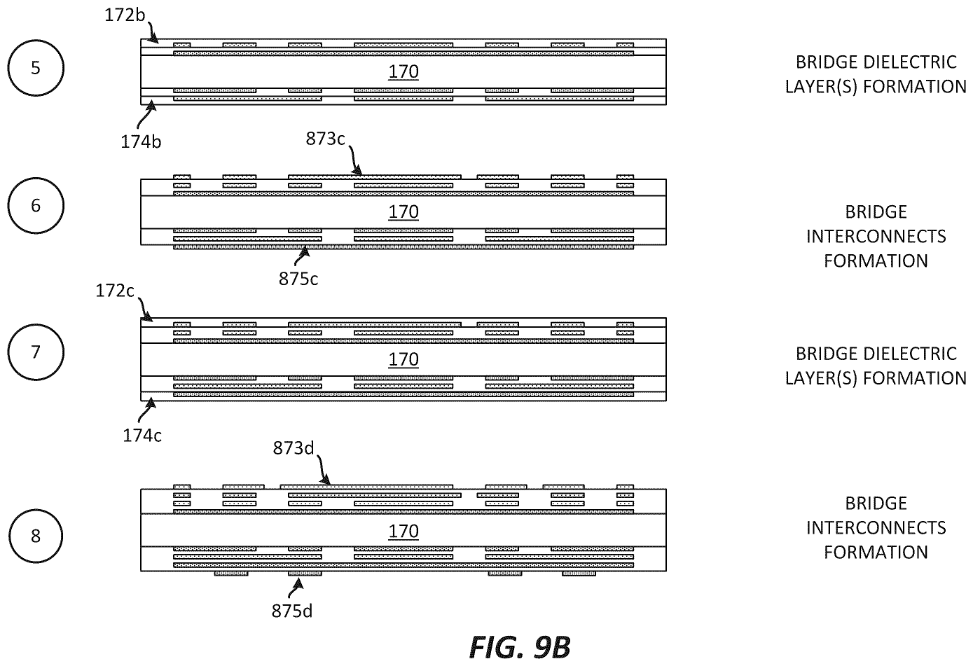

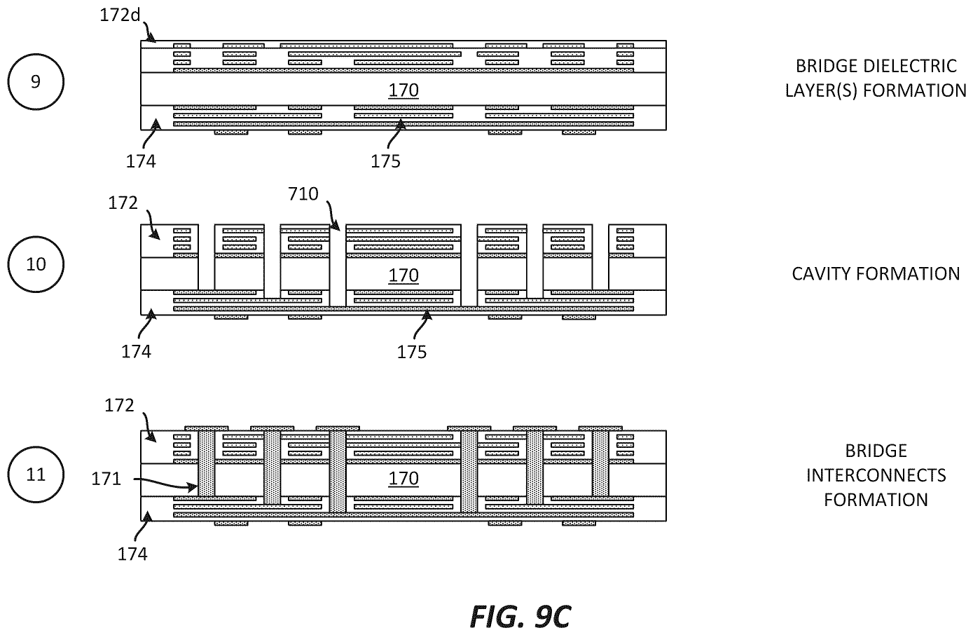

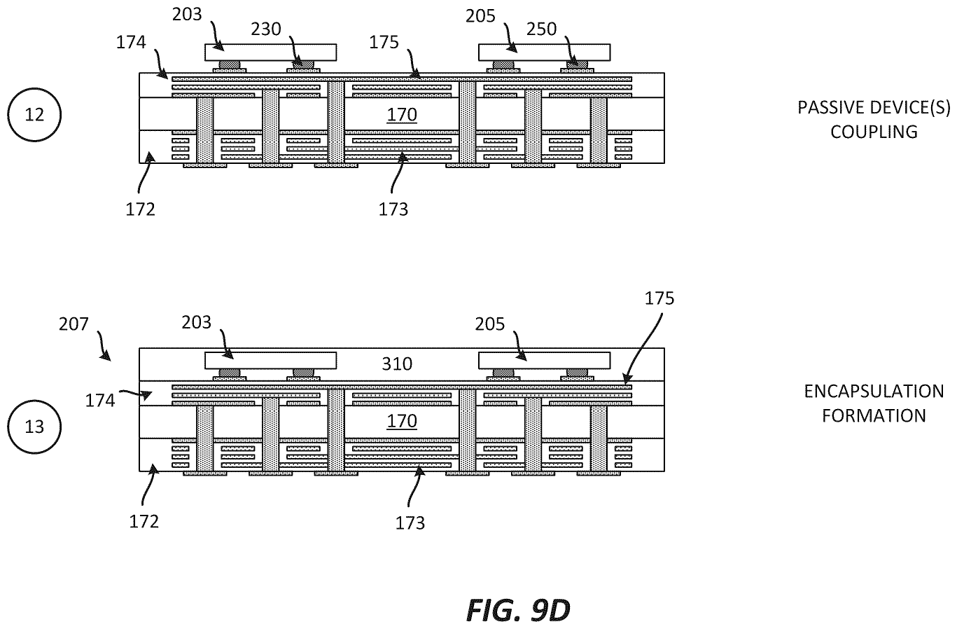

In some implementations, fabricating a bridge includes several processes. FIGS. 9A-9D illustrate an exemplary sequence for providing or fabricating a bridge. In some implementations, the sequence of FIGS. 9A-9D may be used to provide or fabricate the bridge 207. However, the process of FIGS. 9A-9D may be used to fabricate any of the bridges (e.g., 107, 707) described in the disclosure.

It should be noted that the sequence of FIGS. 9A-9D may combine one or more stages in order to simplify and/or clarify the sequence for providing or fabricating a bridge. In some implementations, the order of the processes may be changed or modified. In some implementations, one or more of processes may be replaced or substituted without departing from the scope of the disclosure. FIGS. 9A-9D may illustrate a sequence where the front side and the back side of the bridge are fabricated concurrently.

Stage 1, as shown in FIG. 9A, illustrates a state after a bridge substrate 170 is provided. The bridge substrate 170 may include a silicon substrate.

Stage 2 illustrates a state after a plurality of bridge interconnects are formed over a first surface of the bridge substrate 170 and over a second surface of the bridge substrate 170. The plurality of bridge interconnects 873a may be formed above (e.g., above a first surface of bridge substrate) the bridge substrate 170 and the plurality of bridge interconnects 875a may be formed under (e.g., under a second surface of bridge substrate) the bridge substrate 170. A plating process may be used to form the plurality of bridge interconnects (e.g., 873a, 875a).

Stage 3 illustrates a state after a bridge dielectric layer 172a is formed over the first surface of the bridge substrate 170 and the plurality of bridge interconnects 873a. Stage 3 also illustrates a state after a bridge dielectric layer 174a is formed over the second surface of the bridge substrate 170 and the plurality of bridge interconnects 875a. A deposition and/or lamination process may be used to form the bridge dielectric layers (e.g., 172a, 174a).

Stage 4 illustrates a state after a plurality of bridge interconnects are formed over the bridge dielectric layer 172a and over the bridge dielectric layer 174a. For example, the plurality of bridge interconnects 873b may be formed above the bridge dielectric layer 172a and the plurality of bridge interconnects 875b may be formed under the bridge dielectric layer 174a. A plating process may be used to form the plurality of bridge interconnects (e.g., 873b, 875b).

Stage 5, as shown in FIG. 9B, illustrates a state after a bridge dielectric layer 172b is formed over the plurality of bridge interconnects 873b and the bridge dielectric layer 172a. Stage 5 also illustrates a state after a bridge dielectric layer 174b is formed over the plurality of bridge interconnects 875b and the bridge dielectric layer 174a. A deposition and/or lamination process may be used to form the bridge dielectric layers (e.g., 172b, 174b).

Stage 6 illustrates a state after a plurality of bridge interconnects are formed over the bridge dielectric layer 172b and over the bridge dielectric layer 174b. The plurality of bridge interconnects 873c may be formed above the bridge dielectric layer 172b and the plurality of bridge interconnects 875c may be formed under the bridge dielectric layer 174b. A plating process may be used to form the plurality of bridge interconnects (e.g., 873c, 875c).

Stage 7 illustrates a state after a bridge dielectric layer 172c is formed over the plurality of bridge interconnects 873c. Stage 7 also illustrates a state after a bridge dielectric layer 174c is formed over the plurality of bridge interconnects 875c. A deposition and/or lamination process may be used to form the bridge dielectric layers (e.g., 172c, 174c).

Stage 8 illustrates a state after a plurality of bridge interconnects are formed over the bridge dielectric layer 172c and over the bridge dielectric layer 174c. The plurality of bridge interconnects 873d may be formed above the bridge dielectric layer 172c and the plurality of bridge interconnects 875d may be formed under the bridge dielectric layer 174c. A plating process may be used to form the plurality of bridge interconnects (e.g., 873d, 875d).

Stage 9, as shown in FIG. 9C, illustrates a state after a bridge dielectric layer 172d is formed over the plurality of bridge interconnects 873d and the bridge dielectric layer 172c. A deposition and/or lamination process may be used to form the bridge dielectric layer (e.g., 172d).

Stage 10 illustrates a state after a plurality of cavities 710 are formed in the bridge substrate 170, the at least one bridge dielectric layer 172 and/or the at least one bridge dielectric layer 174. The plurality of cavities 710 may be formed using a laser ablation process. The bridge dielectric layer 172 may represent and/or include the bridge dielectric layer 172a, 172b, 172c and/or 172d. The bridge dielectric layer 174 may represent and/or include the bridge dielectric layer 174a, 174b, and/or 174c.

Stage 11 illustrates a state after a plurality of bridge interconnects 171 that extend through the bridge substrate 170, the at least one bridge dielectric layer 172 and/or the at least one bridge dielectric layer 174 is formed. A plating process may be used to form the plurality of bridge interconnects 171.

Stage 12, as shown in FIG. 9D, illustrates a state after a passive device 203 and a passive device 205 are coupled to the plurality of bridge interconnects 175. The passive device 203 may be coupled to the plurality of bridge interconnects 175 through the plurality of solder interconnects 230. The passive device 205 may be coupled to the plurality of bridge interconnects 175 through the plurality of solder interconnects 250. A solder reflow process may be used to couple the passive device 203 and/or the passive device 205.

Stage 13 illustrates a state after an encapsulation layer 310 is formed. The encapsulation layer 310 is coupled to a surface of the bridge 207. For example, the encapsulation layer 310 may be coupled to a surface of the at least one bridge dielectric layer 174. The encapsulation layer 310 may encapsulate the passive device 203 and/or the passive device 205. The encapsulation layer 310 may include a mold, a resin and/or an epoxy. The encapsulation layer 310 may be a means for encapsulation. The encapsulation layer 310 may be provided by using a compression and transfer molding process, a sheet molding process, or a liquid molding process. Stage 13 illustrates an example of the bridge 207 that includes a bridge substrate 170, a plurality of bridge interconnects 171, at least one bridge dielectric layer 172, a plurality of bridge interconnects 173, at least one bridge dielectric layer 174, a plurality of bridge interconnects 175, a passive device 203, a passive device 205 and an encapsulation layer 310.

### Exemplary Flow Diagram of a Method for Fabricating a Bridge

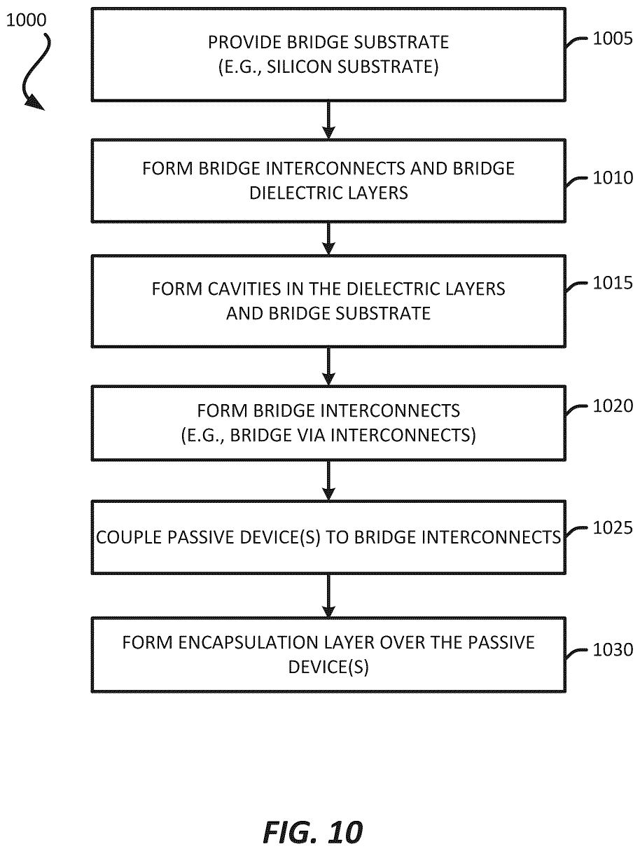

In some implementations, fabricating a bridge includes several processes. FIG. 10 illustrates an exemplary flow diagram of a method 1000 for providing or fabricating a bridge. In some implementations, the method 1000 of FIG. 10 may be used to provide or fabricate the bridge 207 described in the disclosure. However, the method 1000 may be used to provide or fabricate any of the bridges (e.g., 107, 707) described in the disclosure.

It should be noted that the method 1000 of FIG. 10 may combine one or more processes in order to simplify and/or clarify the method for providing or fabricating a bridge. In some implementations, the order of the processes may be changed or modified.

The method provides (at 1005) a bridge substrate (e.g., 170). The bridge substrate 170 may include a silicon substrate. Stage 1 of FIG. 9A, illustrates and describes an example of providing a bridge substrate.

The method forms (at 1010) bridge interconnects (e.g., 173, 175) and bridge dielectric layers (e.g., 172, 174) over surfaces of the bridge substrate. For example, a plurality of bridge interconnects may be formed over a first surface of the bridge substrate 170 and over a second surface of the bridge substrate 170. The plurality of bridge interconnects 873a may be formed above the bridge substrate 170 and the plurality of bridge interconnects 875a may be formed under the bridge substrate 170. A plating process may be used to form the plurality of bridge interconnects (e.g., 873a, 875a). In another example, a bridge dielectric layer 172a may be formed over the first surface of the bridge substrate 170 and the plurality of bridge interconnects 873a. In another example, a bridge dielectric layer 174a may be formed over the second surface of the bridge substrate 170 and the plurality of bridge interconnects 875a. A deposition and/or lamination process may be used to form the bridge dielectric layers (e.g., 172a. 174a). The above process may be iteratively performed to form several bridge interconnects and/or bridge dielectric layers. Stages 2 through 9 of FIGS. 9A-9C illustrate and describe examples of forming bridge interconnects and bridge dielectric layers.

The method forms (at 1015) a plurality of cavities (e.g., 710) in the bridge substrate 170, the at least one bridge dielectric layer 172 and/or the at least one bridge dielectric layer 174. The plurality of cavities 710 may be formed using a laser ablation process. The plurality of cavities 710 may extend through the at least one bridge dielectric layer 172, the bridge substrate 170 and/or the at least one bridge dielectric layer 174. Stage 10 of FIG. 9C illustrates and describes an example of forming cavities.

The method form (at 1020) a plurality of bridge interconnects (e.g., 171) in the plurality of cavities 710. The plurality of bridge interconnects 171 may extend through the at least one bridge dielectric layer 172, the bridge substrate 170, and/or the at least one bridge dielectric layer 174. A plating process may be used to form the plurality of bridge interconnects 171. The plurality of bridge interconnects 171 may be coupled to the plurality of bridge interconnects 173 and/or the plurality of bridge interconnects 175. Stage 11 of FIG. 9C illustrates and describes an example of forming bridge interconnects.

The method couples (at 1025) one or more passive device(s) (e.g., 203, 205) to the bridge interconnects. For example, the passive device 203 may be coupled to the plurality of bridge interconnects 175 through the plurality of solder interconnects 230, and the passive device 205 may be coupled to the plurality of bridge interconnects 175 through the plurality of solder interconnects 250. A solder reflow process may be used to couple the passive device 203 and/or the passive device 205. Stage 12 of FIG. 9D illustrates and describes an example of coupling passive devices to bridge interconnects.

The method forms (at 1030) an encapsulation layer (e.g., 310). For example, the encapsulation layer 310 may be coupled to a surface of the bridge 207. The encapsulation layer 310 may encapsulate the passive device 203 and/or the passive device 205. The encapsulation layer 310 may include a mold, a resin and/or an epoxy. The encapsulation layer 310 may be a means for encapsulation. The encapsulation layer 310 may be provided by using a compression and transfer molding process, a sheet molding process, or a liquid molding process. Stage 13 of FIG. 9D illustrates and describes an example of forming an encapsulation layer.

It is noted that the method 1000 of FIG. 10 may be modified to fabricate a bridge in a manner described in FIGS. 8A-8F. In such a implementations, the method may form bridge dielectric layer(s) and bridge interconnects for a front side of the bridge, then interconnects in the bridge substrate, and then bridge dielectric layer(s) and bridge interconnects for a back side of the bridge are formed. Once the front side and back side bridge interconnects are fabricated, passive devices may be coupled to the bridge and an encapsulation layer may be formed.

### Exemplary Sequence for Fabricating a Package Comprising a Bridge

In some implementations, fabricating a package includes several processes. FIGS. 11A-11D illustrate an exemplary sequence for providing or fabricating a package comprising a bridge. In some implementations, the sequence of FIGS. 11A-11D may be used to provide or fabricate the package 400. However, the process of FIGS. 11A-11D may be used to fabricate any of the packages that include a bridge described in the disclosure.

It should be noted that the sequence of FIGS. 11A-11D may combine one or more stages in order to simplify and/or clarify the sequence for providing or fabricating a package comprising a bridge. In some implementations, the order of the processes may be changed or modified. In some implementations, one or more of processes may be replaced or substituted without departing from the scope of the disclosure.

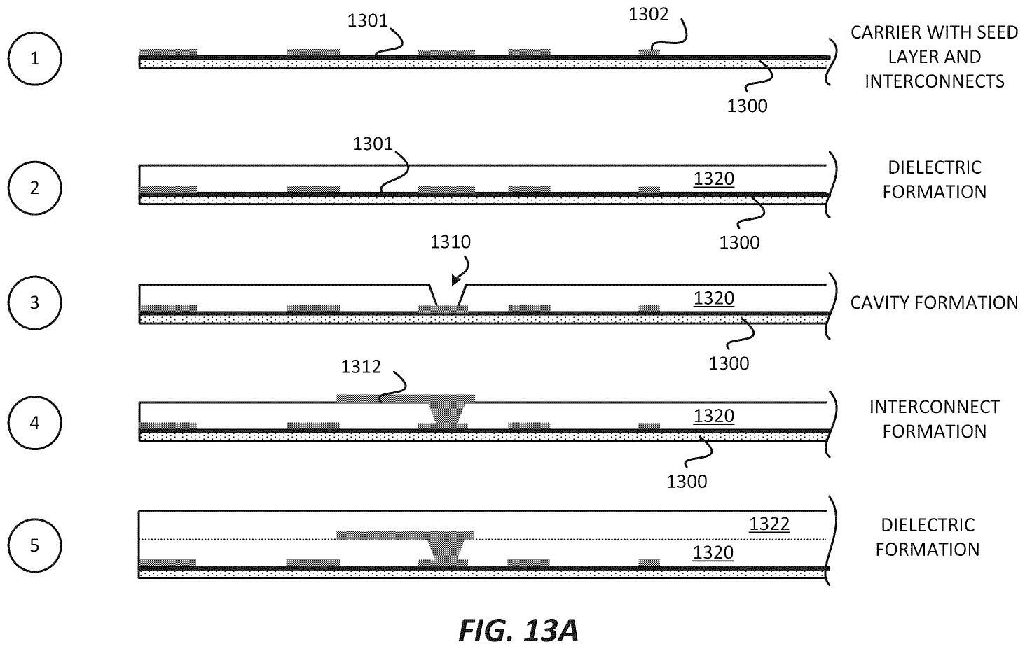

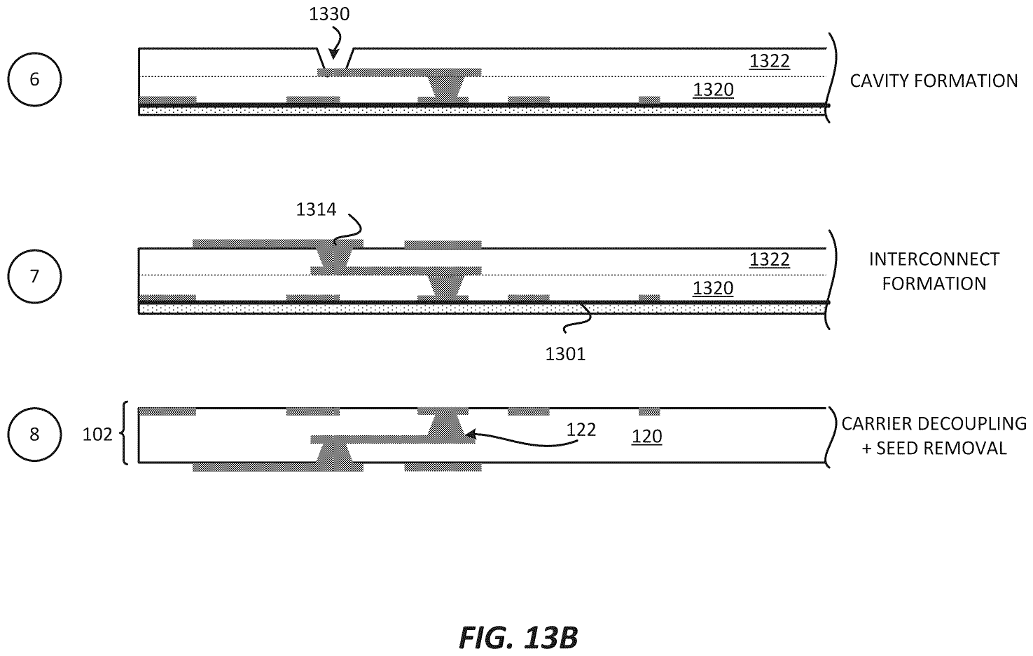

Stage 1 of FIG. 11A, illustrates a state after a substrate 102 and a carrier 1100 are provided. The substrate 102 may be coupled to and located over the carrier 1100. The substrate 102 may include at least one dielectric layer 120 and a plurality of interconnects 122. FIGS. 13A-13B illustrate an example of fabricating a substrate that includes at least one dielectric layer and a plurality of interconnects.

Stage 2 illustrates a state after a cavity 209 is formed in the substrate 102. A laser ablation process and/or an etching process may be used to form the cavity 209. The cavity 209 may extend through (e.g., partially or completely) the substrate 102 (e.g., extend through the at least one dielectric layer 120 of the substrate 102). A surface of the carrier 1100 may be exposed through the cavity 209.

Stage 3 illustrates a state after a bridge 207 is place in the cavity 209 and over the carrier 1100. A pick and place process may be used to position the bridge 207 in the cavity 209. Different implement may position different bridges (e.g., 107, 707) in the cavity 209. The bridge 207 may or may not include an encapsulation layer. The bridge 207 may or may not include one or more passive devices. The bridge 207 may be located over and/or coupled to the carrier 1100.

Stage 4 of FIG. 11B illustrates a state after a dielectric layer 1120 is formed over the bridge 207. The dielectric layer 1120 may be similar to the at least one dielectric layer 120. The dielectric layer 1120 may be formed along portions of the side of the bridge 207 that are located in the cavity 209. The dielectric layer 1120 may fill portions of the cavity 209 of the substrate 102. In some implementations, some portions of the cavity 209 is filled with the dielectric layer 1120. In some implementations, a majority of the space, if not all of the space, in the cavity 209 that is not occupied by the bridge 207 may be filled with the dielectric layer 1120. A deposition and/or lamination process may be used to form the dielectric layer 1120. In some implementations, instead of the dielectric layer 1120, an encapsulation layer that is similar to the encapsulation layer 310 may be used. The encapsulation layer that is provided over the bridge 207 may be provided by using a compression and transfer molding process, a sheet molding process, or a liquid molding process.

Stage 5 illustrates state after a plurality of cavities 1121 are formed in the dielectric layer 1120. A laser ablation process and/or an etching process (e.g., lithography process) may be used to form the plurality of cavities 1121. The dielectric layer 1120 may be considered part of the dielectric layer 120. Thus, the dielectric layer 120 may include the dielectric layer 1120. The plurality of cavities 1121 may be considered to be formed in the dielectric layer 120. The plurality of cavities 1121 may expose part of the bridge 207. For example, the plurality of cavities 1121 may expose bridge interconnects of the bridge 207.

Stage 6 illustrates after a plurality of bridge interconnects 1123 are formed over the at least one dielectric layer 120 and/or the dielectric layer 1120. The dielectric layer 1120 may considered part of the at least one dielectric layer 120. The plurality of bridge interconnects 1123 may be coupled to the plurality of interconnects 122 and to bridge interconnects (e.g., 173) of the bridge 207. A plating process may be used to form the plurality of bridge interconnects 1123.

Stage 7 of FIG. 11C, illustrates a state after the carrier 1100 is decoupled from the substrate 102 and the bridge 207. The carrier 1100 may be removed and/or detached from the substrate 102 and/or the bridge 207.

Stage 8 illustrates a state after a plurality of cavities 1143 are formed in the encapsulation layer 310. A laser ablation and/or an etching process may be used to form the plurality of cavities 1143.

Stage 9 illustrates a state after a plurality of interconnects 1145 are formed. The plurality of interconnects 1145 may be formed in and over the encapsulation layer 310. The plurality of interconnects 1145 may be formed over the at least one dielectric layer 120. The plurality of interconnects 1135 may include interconnects that are considered part of the substrate 102, and/or bridge interconnects that are considered part of the bridge 207. Part or all of the plurality of interconnects 1145 may be considered part of the plurality of interconnects 122.

Stage 10 illustrate a state after a dielectric layer 1160 is formed over the at least one dielectric layer 120 and/or the encapsulation layer 310. A deposition and/or lamination process may be used to form the dielectric layer 1160. The dielectric layer 1160 may be similar to the at least one dielectric layer 120. The dielectric layer 1160 may be considered part of the at least one dielectric layer 120.

Stage 11 illustrates a state after integrated devices are coupled to the substrate 102. For example, the integrated device 103 is coupled to the substrate 102 through a plurality of solder interconnects 130, and the integrated device 105 is coupled to the substrate 102 through a plurality of solder interconnects 150. A solder reflow process may be used to couple the integrated devices (e.g., 103, 105) to the substrate 102.

Stage 12 illustrates a state after a plurality of solder interconnects 110 is coupled to the substrate 102. The plurality of solder interconnects 110 is coupled to the plurality of interconnects 122 of the substrate 102. A solder reflow process may be used to couple the plurality of solder interconnects 110 to the substrate 102. Stage 12 may illustrate an example of the package 400 that includes a substrate 102, a bridge 207, an integrated device 103 and an integrated device 105.

### Exemplary Flow Diagram of a Method for Fabricating a Package Comprising a Bridge

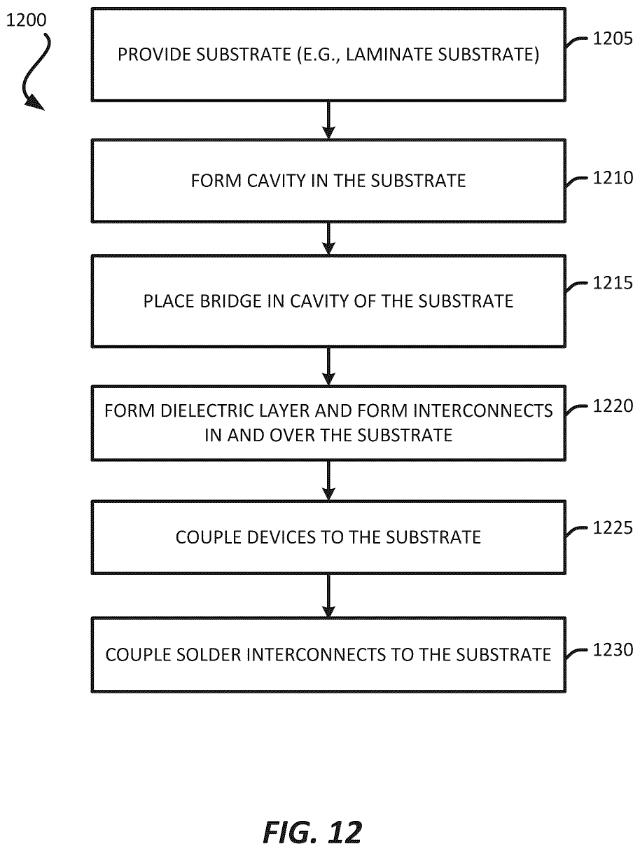

FIG. 12 illustrates an exemplary flow diagram of a method 1200 for providing or fabricating a package that includes a bridge. In some implementations, the method 1200 of FIG. 12 may be used to provide or fabricate the package 400 described in the disclosure. However, the method 1200 may be used to provide or fabricate any of the packages described in the disclosure.

It should be noted that the method 1200 of FIG. 12 may combine one or more processes in order to simplify and/or clarify the method for providing or fabricating a package. In some implementations, the order of the processes may be changed or modified.

The method provides (at 1205) a substrate (e.g., 102) that includes at least one dielectric layer (e.g., 120) and a plurality of interconnects (e.g., 122). The substrate 102 may be coupled to a carrier 1100. The substrate may be a laminate substrate. FIGS. 13A-13B illustrate an example of fabricating a substrate that includes at least one dielectric layer and a plurality of interconnects. Stage 1 of FIG. 11A, illustrates and describes an example of providing a substrate and a carrier.

The method forms (at 1210) a cavity (e.g., 209) in the substrate 102. A laser ablation process and/or an etching process may be used to form the cavity 209. The cavity 209 may extend through (e.g., partially or completely) the substrate 102 (e.g., extend through the at least one dielectric layer 120 of the substrate 102). A surface of the carrier 1100 may be exposed through the cavity 209. Stage 2 of FIG. 11A illustrates and describes an example of forming a cavity in the substrate.

The method places (at 1215) a bridge (e.g., 207) in the cavity 209 of the substrate 102 and over the carrier 1100. A pick and place process may be used to position the bridge 207 in the cavity 209 of the substrate 102. Different implement may place different bridges (e.g., 107, 207) in the cavity 209. The bridge 207 may or may not include at least one passive device. The bridge 207 may or may not include an encapsulation layer. The bridge 207 may be located over and/or coupled to the carrier 1100. Stage 3 of FIG. 11A illustrates and describes an example of placing a bridge in a cavity of a substrate.

The method forms (at 1220) a dielectric layer and interconnects (e.g., bridge interconnects) over the bridge and/or the substrate. For example, a dielectric layer 1120 may be formed over the bridge 207. The dielectric layer 1120 may be similar to the at least one dielectric layer 120. The dielectric layer 1120 may be formed along portions of the side of the bridge 207 that are located in the cavity 209. The dielectric layer 1120 may fill portions of the cavity 209 of the substrate 102. A deposition and/or lamination process may be used to form the dielectric layer 1120. In some implementations, the dielectric layer 1120 may be an encapsulation layer that is similar to the encapsulation layer 310. The encapsulation layer that is provided over the bridge 207 may be provided by using a compression and transfer molding process, a sheet molding process, or a liquid molding process.

Forming the interconnects may include forming cavities in the dielectric layer and performing a plating process. For example, a plurality of cavities 1121 may be formed in the dielectric layer 1120. A laser ablation process and/or an etching process (e.g., lithography process) may be used to form the plurality of cavities 1121. A plurality of bridge interconnects 1123 may be formed over the at least one dielectric layer 120 and/or the dielectric layer 1120. The dielectric layer 1120 may considered part of the at least one dielectric layer 120. The plurality of bridge interconnects 1123 may be coupled to the plurality of interconnects 122 and to bridge interconnects (e.g., 173) of the bridge 207. A plating process may be used to form the plurality of bridge interconnects 1123.

The carrier 1100 is decoupled from the substrate 102 and the bridge 207. The carrier 1100 may be removed and/or detached from the substrate 102 and/or the bridge 207. A plurality of cavities 1143 are formed in the encapsulation layer 310. A laser ablation and/or an etching process may be used to form the plurality of cavities 1143. A plurality of interconnects 1145 may be formed. The plurality of interconnects 1145 may be formed in and over the encapsulation layer 310. The plurality of interconnects 1145 may be formed over the at least one dielectric layer 120. The plurality of interconnects 1135 may include interconnects that are considered part of the substrate 102, and/or bridge interconnects that are considered part of the bridge 207. Part or all of the plurality of interconnects 1145 may be considered part of the plurality of interconnects 122. A dielectric layer 1160 may be formed over the at least one dielectric layer 120 and/or the encapsulation layer 310. A deposition and/or lamination process may be used to form the dielectric layer 1160. The dielectric layer 1160 may be similar to the at least one dielectric layer 120. The dielectric layer 1160 may be considered part of the at least one dielectric layer 120. Stages 4 through 10 of FIGS. 11B-11C illustrates examples of forming dielectric layer(s), forming cavities and forming interconnects.

The method couples (at 1025) at least one integrated device to the substrate. For example, the integrated device 103 may be coupled to the substrate 102 through a plurality of solder interconnects 130, and the integrated device 105 may be coupled to the substrate 102 through a plurality of solder interconnects 150. A solder reflow process may be used to couple the integrated devices (e.g., 103, 105) to the substrate 102. Stage 11 of FIG. 11D illustrates and describes an example of coupling integrated devices to a substrate.

The method couples (at 1230) a plurality of solder interconnects to the substrate. For example, a plurality of solder interconnects 110 may be coupled to the substrate 102. The plurality of solder interconnects 110 may be coupled to the plurality of interconnects 122 of the substrate 102. A solder reflow process may be used to couple the plurality of solder interconnects 110 to the substrate 102. Stage 12 of FIG. 11D illustrates and describes an example of coupling solder interconnects to a substrate.

### Exemplary Sequence for Fabricating a Substrate

In some implementations, fabricating a substrate includes several processes. FIGS. 13A-13B illustrate an exemplary sequence for providing or fabricating a substrate. In some implementations, the sequence of FIGS. 13A-13B may be used to provide or fabricate the substrate 102. However, the process of FIGS. 13A-13B may be used to fabricate any of the substrates described in the disclosure.

It should be noted that the sequence of FIGS. 13A-13B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 13A, illustrates a state after a carrier 1300 is provided. A seed layer 1301 and interconnects 1302 may be located over the carrier 1300. The interconnects 1302 may be located over the seed layer 1301. A plating process and etching process may be used to form the interconnects 1302. In some implementations, the carrier 1300 may be provided with the seed layer 1301 and a metal layer that is patterned to form the interconnects 1302. The interconnects 1302 may represent at least some of the interconnects from the plurality of interconnects 142.

Stage 2 illustrates a state after a dielectric layer 1320 is formed over the carrier 1300, the seed layer 1301 and the interconnects 1302. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.

Stage 3 illustrates a state after a plurality of cavities 1310 is formed in the dielectric layer 1320. The plurality of cavities 1310 may be formed using an etching process (e.g., photo etching process) or laser process.

Stage 4 illustrates a state after interconnects 1312 are formed in and over the dielectric layer 1320, including in and over the plurality of cavities 1310. For example, a via, pad and/or traces may be formed. A plating process may be used to form the interconnects.

Stage 5 illustrates a state after a dielectric layer 1322 is formed over the dielectric layer 1320 and the interconnects 1312. A deposition and/or lamination process may be used to form the dielectric layer 1322. The dielectric layer 1322 may include prepreg and/or polyimide. The dielectric layer 1322 may include a photo-imageable dielectric. However, different implementations may use different materials for the dielectric layer.

Stage 6, as shown in FIG. 13B, illustrates a state after a plurality of cavities 1330 is formed in the dielectric layer 1322. The plurality of cavities 1330 may be formed using an etching process (e.g., photo etching process) or laser process.

Stage 7 illustrates a state after interconnects 1314 are formed in and over the dielectric layer 1322, including in and over the plurality of cavities 1330. For example, a via, pad and/or traces may be formed. A plating process may be used to form the interconnects.

Stage 8 illustrates a state after the carrier 1300 is decoupled (e.g., detached, removed, grinded out) from at least one dielectric layer 140 and the seed layer 1301, portions of the seed layer 1301 are removed (e.g., etched out), leaving the substrate 102 that includes at least one dielectric layer 120 and the plurality of interconnects 122.

### Exemplary Flow Diagram of a Method for Fabricating a Substrate

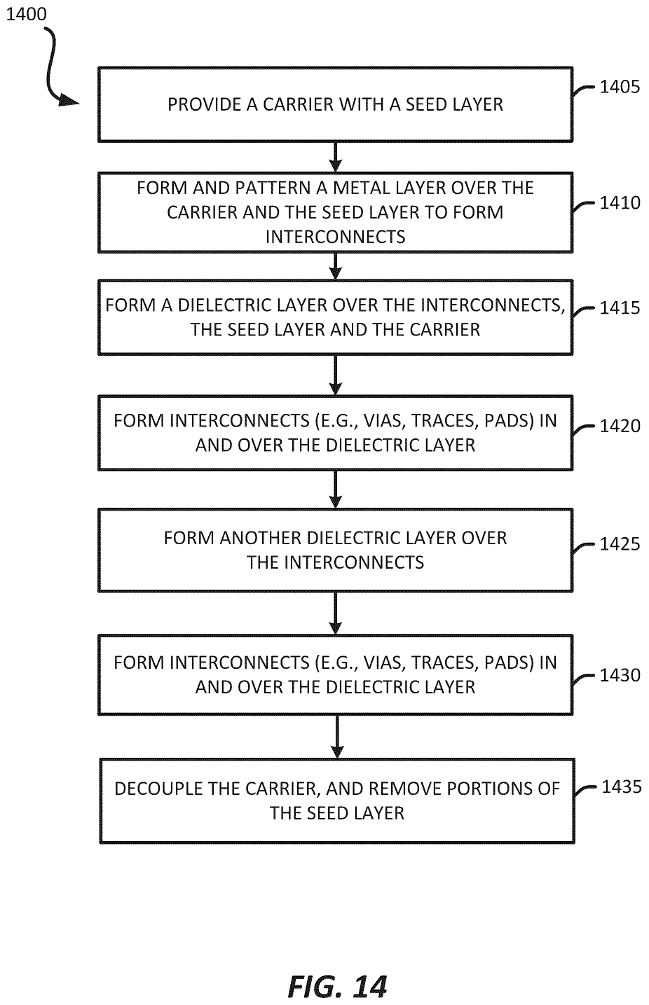

In some implementations, fabricating a substrate includes several processes. FIG. 14 illustrates an exemplary flow diagram of a method 1400 for providing or fabricating a substrate. In some implementations, the method 1400 of FIG. 14 may be used to provide or fabricate the substrate(s) of the disclosure. For example, the method 1400 of FIG. 14 may be used to fabricate the substrate 102.

It should be noted that the method 1400 of FIG. 14 may combine one or more processes in order to simplify and/or clarify the method for providing or fabricating a substrate. In some implementations, the order of the processes may be changed or modified.

The method provides (at 1405) a carrier (e.g., 1300). Different implementations may use different materials for the carrier 1300. The carrier 1300 may include a seed layer (e.g., 1301). The seed layer 1301 may include a metal (e.g., copper). The carrier may include a substrate, glass, quartz and/or carrier tape. Stage 1 of FIG. 13A illustrates and describes an example of a carrier with a seed layer that is provided.

The method forms and patterns (at 1410) interconnects over the carrier 1300 and the seed layer 1301. A metal layer may be patterned to form interconnects. A plating process may be used to form the metal layer and interconnects. In some implementations, the carrier and seed layer may include a metal layer. The metal layer is located over the seed layer and the metal layer may be patterned to form interconnects (e.g., 1302). Stage 1 of FIG. 13A illustrates and describes an example of forming and patterning interconnects over a seed layer and a carrier.

The method forms (at 1415) a dielectric layer 1320 over the seed layer 1301, the carrier 1300 and the interconnects 1302. A deposition and/or lamination process may be used to form the dielectric layer 1320. The dielectric layer 1320 may include prepreg and/or polyimide. The dielectric layer 1320 may include a photo-imageable dielectric. Forming the dielectric layer 1320 may also include forming a plurality of cavities (e.g., 1310) in the dielectric layer 1320. The plurality of cavities may be formed using an etching process (e.g., photo etching) or laser process. Stages 2-3 of FIG. 13A illustrate and describe an example of forming a dielectric layer and cavities in the dielectric layer.

The method forms (at 1420) interconnects in and over the dielectric layer. For example, the interconnects 1312 may be formed in and over the dielectric layer 1320. A plating process may be used to form the interconnects. Forming interconnects may include providing a patterned metal layer over and/or in the dielectric layer. Forming interconnects may also include forming interconnects in cavities of the dielectric layer. Stage 4 of FIG. 13A illustrates and describes an example of forming interconnects in and over a dielectric layer.

The method forms (at 1425) a dielectric layer 1322 over the dielectric layer 1320 and the interconnects 1312. A deposition and/or lamination process may be used to form the dielectric layer 1322. The dielectric layer 1322 may include prepreg and/or polyimide. The dielectric layer 1322 may include a photo-imageable dielectric. Forming the dielectric layer 1322 may also include forming a plurality of cavities (e.g., 1330) in the dielectric layer 1322. The plurality of cavities may be formed using an etching process (e.g., photo etching) or laser process. Stages 5-6 of FIGS. 13A-13B illustrate and describe an example of forming a dielectric layer and cavities in the dielectric layer.

The method forms (at 1430) interconnects in and over the dielectric layer. For example, the interconnects 1314 may be formed in and over the dielectric layer 1322. A plating process may be used to form the interconnects. Forming interconnects may include providing a patterned metal layer over and/or in the dielectric layer. Forming interconnects may also include forming interconnects in cavities of the dielectric layer. Forming interconnects may include forming post interconnects. Stage 7 of FIG. 13B illustrates and describes an example of forming interconnects in and over a dielectric layer, including forming post interconnects.

The method decouples (at 1435) the carrier (e.g., 1300) from the seed layer (e.g., 1301). The carrier 1300 may be detached and/or grinded off. The method may also remove (at 1435) portions of the seed layer (e.g., 1301). An etching process may be used to remove portions of the seed layer 1301. Stage 8 of FIG. 13B illustrates and describes an example of decoupling a carrier and seed layer removal.

### Exemplary Electronic Devices

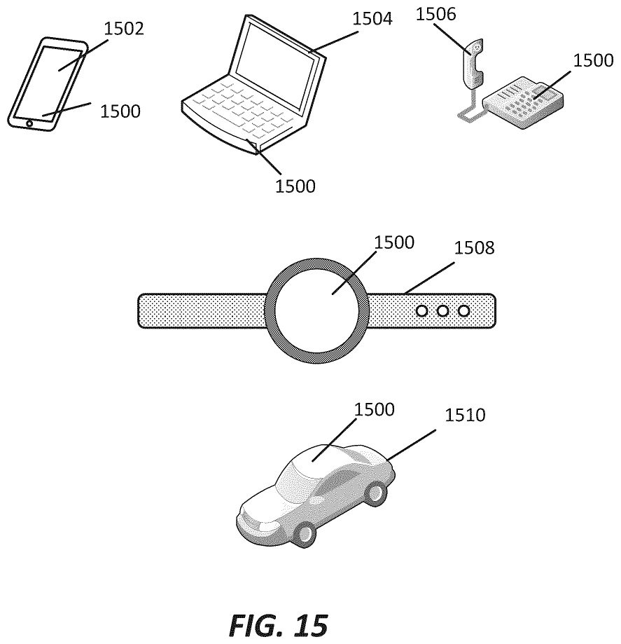

FIG. 15 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1502, a laptop computer device 1504, a fixed location terminal device 1506, a wearable device 1508, or automotive vehicle 1510 may include a device 1500 as described herein. The device 1500 may be, for example, any of the devices and/or integrated circuit (IC) packages described herein. The devices 1502, 1504, 1506 and 1508 and the vehicle 1510 illustrated in FIG. 15 are merely exemplary. Other electronic devices may also feature the device 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-7, 8A-8F, 9A-9D, 10, 11A-11D, 12, 13A-13B, and 14-15 may be rearranged and/or combined into a single component, process, feature or function or embodied in several components, processes, or functions. Additional elements, components, processes, and/or functions may also be added without departing from the disclosure. It should also be noted FIGS. 1-7, 8A-8F, 9A-9D, 10, 11A-11D, 12, 13A-13B, and 14-15 and its corresponding description in the present disclosure is not limited to dies and/or ICs. In some implementations, FIGS. 1-7, 8A-8F, 9A-9D, 10, 11A-11D, 12, 13A-13B, and 14-15 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’,”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising a substrate; a bridge located in the substrate, a first integrated device coupled to the substrate; and a second integrated device coupled to the substrate. The bridge comprises a bridge substrate; at least one first bridge dielectric layer coupled to a first surface of the bridge substrate; at least one first bridge interconnect located in the at least one first bridge dielectric layer; at least one second bridge dielectric layer coupled to a second surface of the bridge substrate; at least one second bridge interconnect located in the at least one second bridge dielectric layer; and at least one bridge interconnect that extends through the at least one first bridge dielectric layer and the bridge substrate.

Aspect 2: The package of aspect 1, wherein the at least one first bridge interconnect is configured to provide a first electrical path for input/output (I/O) signals, and wherein the at least one second bridge interconnect is configured to provide a second electrical path for power.

Aspect 3: The package of aspect 1, wherein the at least one first bridge interconnect is configured to provide a first electrical path for input/output (I/O) signals, and wherein the at least one second bridge interconnect is configured to provide a second electrical path for ground.

Aspect 4: The package of aspect 3, wherein the at least one second bridge interconnect is configured to provide another electrical path for power.

Aspect 5: The package of aspects 1 through 4, further comprising a passive device coupled to the at least one second bridge interconnect.

Aspect 6: The package of aspect 5, further comprising an encapsulation layer that encapsulates the passive device.

Aspect 7: The package of aspects 5 through 6, wherein the bridge includes a front side and a back side, and wherein the passive device is coupled to the back side of the bridge.

Aspect 8: The package of aspect 7, wherein the bridge is configured to provide at least one electrical path for power, and wherein the power that travels through the bridge travels through the back side of the bridge.

Aspect 9: The package of aspects 1 through 8, wherein the first integrated device is configured to be electrically coupled to the bridge.

Aspect 10: The package of aspects 1 through 9, wherein the first integrated device is configured to be electrically coupled to the second integrated device through the substrate and the bridge.

Aspect 11: The package of aspect 10, wherein an input and/or output (I/O) signal is configured to travel between the first integrated device and the second integrated device through an electrical path that includes interconnects from the substrate and bridge interconnects from the bridge.

Aspect 12: The package of aspects 1 through 11, wherein the first integrated device includes a first chiplet and the second integrated device includes a second chiplet.

Aspect 13: The package of aspects 1 through 12, wherein the at least one first bridge interconnect includes a first thickness, wherein the at least one second bridge interconnect has a second thickness, and wherein the second thickness is greater than the first thickness.

Aspect 14: The package of aspect 13, wherein the first thickness is in a first range of about 1-2 micrometers, and wherein the second thickness is in a second range of about 3-6 micrometers.

Aspect 15: A device comprising a package that includes a substrate; a bridge located in the substrate, a first integrated device coupled to the substrate; and a second integrated device coupled to the substrate. The bridge comprises a bridge substrate; at least one first bridge dielectric layer coupled to a first surface of the bridge substrate; at least one first bridge interconnect located in the at least one first bridge dielectric layer; at least one second bridge dielectric layer coupled to a second surface of the bridge substrate; at least one second bridge interconnect located in the at least one second bridge dielectric layer; and at least one bridge interconnect that extends through the at least one first bridge dielectric layer and the bridge substrate.

Aspect 16: The device of aspect 15, wherein the first integrated device is configured to be electrically coupled to the second integrated device through the substrate and the bridge.

Aspect 17: The device of aspect 16, wherein an input and/or output (I/O) signal is configured to travel between the first integrated device and the second integrated device through an electrical path that includes interconnects from the substrate and bridge interconnects from the bridge.

Aspect 18: The device of aspects 15 through 17, wherein the first integrated device includes a first chiplet and the second integrated device includes a second chiplet.

Aspect 19: The device of aspects 15 through 18, further comprising a passive device coupled to the at least one second bridge interconnect.

Aspect 20: The device of aspect 19, further comprising an encapsulation layer that encapsulates the passive device.

Aspect 21: The device of aspects 19 through 20, wherein the bridge includes a front side and a back side, and wherein the passive device is coupled to the back side of the bridge.

Aspect 22: The device of aspect 21, wherein the bridge is configured to provide at least one electrical path for power, and wherein the power that travels through the bridge travels through the back side of the bridge.

Aspect 23: The device of aspects 15 through 22, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 24: A method for fabricating a package. The method provides a substrate. The method places a bridge in the substrate. The bridge comprises a bridge substrate; at least one first bridge dielectric layer coupled to a first surface of the bridge substrate; at least one first bridge interconnect located in the at least one first bridge dielectric layer; at least one second bridge dielectric layer coupled to a second surface of the bridge substrate; at least one second bridge interconnect located in the at least one second bridge dielectric layer; and at least one bridge interconnect that extends through the at least one first bridge dielectric layer and the bridge substrate. The method couples a first integrated device to the substrate. The method couples a second integrated device to the substrate.

Aspect 25: The method of aspect 24, wherein the package comprises a passive device coupled to the at least one second bridge interconnect.

Aspect 26: The method of aspect 25, wherein the package comprises an encapsulation layer that encapsulates the passive device.

Aspect 27: The method of aspects 25 through 26, wherein the bridge includes a front side and a back side, and wherein the passive device is coupled to the back side of the bridge.

Aspect 28: The method of aspect 27, wherein the bridge is configured to provide at least one electrical path for power, and wherein the power that travels through the bridge travels through the back side of the bridge.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate;
a bridge located in the substrate, wherein the bridge comprises:
a bridge substrate;
at least one first bridge dielectric layer coupled to a first surface of the bridge substrate;
at least one first bridge interconnect located in the at least one first bridge dielectric layer;
at least one second bridge dielectric layer coupled to a second surface of the bridge substrate;
at least one second bridge interconnect located in the at least one second bridge dielectric layer; and
at least one bridge interconnect that extends through the at least one first bridge dielectric layer and the bridge substrate;
a first integrated device coupled to the substrate; and
a second integrated device coupled to the substrate.

2. The package of claim 1,
wherein the at least one first bridge interconnect is configured to provide a first electrical path for input/output (I/O) signals, and
wherein the at least one second bridge interconnect is configured to provide a second electrical path for power.

3. The package of claim 1,
wherein the at least one first bridge interconnect is configured to provide a first electrical path for input/output (I/O) signals, and
wherein the at least one second bridge interconnect is configured to provide a second electrical path for ground.

4. The package of claim 3, wherein the at least one second bridge interconnect is configured to provide another electrical path for power.

5. The package of claim 1, further comprising a passive device coupled to the at least one second bridge interconnect.

6. The package of claim 5, further comprising an encapsulation layer that encapsulates the passive device.

7. The package of claim 5,
wherein the bridge includes a front side and a back side, and
wherein the passive device is coupled to the back side of the bridge.

8. The package of claim 7,
wherein the bridge is configured to provide at least one electrical path for power, and
wherein the power that travels through the bridge travels through the back side of the bridge.

9. The package of claim 1, wherein the first integrated device is configured to be electrically coupled to the bridge.

10. The package of claim 1, wherein the first integrated device is configured to be electrically coupled to the second integrated device through the substrate and the bridge.

11. The package of claim 10, wherein an input and/or output (I/O) signal is configured to travel between the first integrated device and the second integrated device through an electrical path that includes interconnects from the substrate and bridge interconnects from the bridge.

12. The package of claim 1, wherein the first integrated device includes a first chiplet and the second integrated device includes a second chiplet.

13. The package of claim 1,
wherein the at least one first bridge interconnect includes a first thickness,
wherein the at least one second bridge interconnect has a second thickness, and
wherein the second thickness is greater than the first thickness.

14. The package of claim 13,
wherein the first thickness is in a first range of about 1-2 micrometers, and
wherein the second thickness is in a second range of about 3-6 micrometers.

15. A device comprising:
a package comprising:
a substrate;
a bridge located in the substrate, wherein the bridge comprises:
a bridge substrate;
at least one first bridge dielectric layer coupled to a first surface of the bridge substrate;
at least one first bridge interconnect located in the at least one first bridge dielectric layer;
at least one second bridge dielectric layer coupled to a second surface of the bridge substrate;
at least one second bridge interconnect located in the at least one second bridge dielectric layer; and
at least one bridge interconnect that extends through the at least one first bridge dielectric layer and the bridge substrate;
a first integrated device coupled to the substrate; and
a second integrated device coupled to the substrate.

16. The device of claim 15, wherein the first integrated device is configured to be electrically coupled to the second integrated device through the substrate and the bridge.

17. The device of claim 16, wherein an input and/or output (I/O) signal is configured to travel between the first integrated device and the second integrated device through an electrical path that includes interconnects from the substrate and bridge interconnects from the bridge.

18. The device of claim 15, wherein the first integrated device includes a first chiplet and the second integrated device includes a second chiplet.

19. The device of claim 15, further comprising a passive device coupled to the at least one second bridge interconnect.

20. The device of claim 19, further comprising an encapsulation layer that encapsulates the passive device.

21. The device of claim 19,
wherein the bridge includes a front side and a back side, and
wherein the passive device is coupled to the back side of the bridge.

22. The device of claim 21,
wherein the bridge is configured to provide at least one electrical path for power, and
wherein the power that travels through the bridge travels through the back side of the bridge.

23. The device of claim 15, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

24. A method for fabricating a package, comprising:
providing a substrate;
placing a bridge in the substrate, wherein the bridge comprises:
a bridge substrate;
at least one first bridge dielectric layer coupled to a first surface of the bridge substrate;
at least one first bridge interconnect located in the at least one first bridge dielectric layer;
at least one second bridge dielectric layer coupled to a second surface of the bridge substrate;
at least one second bridge interconnect located in the at least one second bridge dielectric layer; and
at least one bridge interconnect that extends through the at least one first bridge dielectric layer and the bridge substrate;
coupling a first integrated device to the substrate; and
coupling a second integrated device to the substrate.

25. The method of claim 24, wherein the package comprises a passive device coupled to the at least one second bridge interconnect.

26. The method of claim 25, wherein the package comprises an encapsulation layer that encapsulates the passive device.

27. The method of claim 25,
wherein the bridge includes a front side and a back side, and
wherein the passive device is coupled to the back side of the bridge.

28. The method of claim 27,
wherein the bridge is configured to provide at least one electrical path for power, and
wherein the power that travels through the bridge travels through the back side of the bridge.
